(19) United States
(12) Patent Application Publication
(10) Pub. No.: US 2026/0275488 A1
(43) Pub. Date: Sep. 17, 2026

(54) DEPOSITION MASK, METHOD OF MANUFACTURING THE SAME, AND ELECTRONIC DEVICE MANUFACTURED BY USING THE SAME

(71) Applicant: Samsung Display Co., LTD., Yongin-si (KR)

(72) Inventor: Dong Uk KIM, Yongin-si (KR)

(21) Appl. No.: 19/384,066

(22) Filed: Nov. 10, 2025

(30) Foreign Application Priority Data
Mar. 14, 2025 (KR) 10-2025-0033481

(51) Int. Cl. C23C 14/04; H10K 71/16

(52) U.S. Cl. CPC C23C 14/042; H10K 71/166

(57) ABSTRACT

A deposition mask includes a mask substrate provided with a cell opening, and a membrane disposed on the mask substrate and provided with pixel openings connected to the cell opening. The membrane includes a first electrode film disposed on the mask substrate, a piezoelectric material film disposed on the first electrode film, and a second electrode film disposed on the piezoelectric material film.

This application claims priority to Korean Patent Application No. 10-2025-0033481, filed on March 14, 2025, and all the benefits accruing therefrom under 35 U.S.C. §119, the content of which in its entirety is herein incorporated by reference.

### BACKGROUND

### 1. Field

The present disclosure relates to a deposition mask, a method of manufacturing the deposition mask, and an electronic device manufactured by using the deposition mask.

### 2. Description of the Related Art

Wearable devices in which a focus is formed at a distance close to user’s eyes have been developed in the form of glasses or a helmet. The wearable device may provide an augmented reality (AR) screen or a virtual reality (VR) screen to a user. For example, the wearable device may be a head mounted display (HMD) device or AR glasses.

In the case of wearable devices such as the HMD device or the AR glasses, a display specification of approximately 3000 pixels per inch (PPI) or higher is desired to allow users to use them for a long time without symptoms of dizziness. To this end, organic light emitting diode on silicon (OLEDoS) technology is emerging for use in a high-resolution small organic light emitting display device. The OLEDoS is a technology in which organic light emitting diodes (OLED) are arranged on a semiconductor substrate on which complementary metal oxide semiconductor (CMOS) elements are arranged.

In order to manufacture a display panel with a high resolution of about 3000 PPI or higher, a high-resolution deposition mask is typically used. For example, the deposition mask may be manufactured by forming a membrane having a plurality of pixel openings on a mask substrate, and partially removing the mask substrate to form cell openings that expose the pixel openings. The pixel openings may be formed by forming the membrane on the mask substrate and then by performing an anisotropic etching process such as a reactive ion etching (RIE) process.

### SUMMARY

A deposition mask may be used as a shadow mask in a deposition process for forming light emitting layers on a backplane substrate. In the deposition process, the backplane substrate may be positioned on the deposition mask, and a deposition source for providing a vapor deposition material may be disposed under the deposition mask. The vapor deposition material may be deposited on the backplane substrate through the pixel openings, thereby forming the light emitting layers on the backplane substrate. However, while performing the deposition process, the membrane of the deposition mask may sag downward due to its own weight. In this case, a distance between the backplane substrate and the deposition mask may become non-uniform, and as a result, pixel position accuracy (PPA), size uniformity, or the like of the light emitting layers may be degraded.

Embodiments of the present disclosure provide a deposition mask capable of improving a problem in which a membrane sags due to its own weight, a method of manufacturing the deposition mask, and an electronic device manufactured by using the deposition mask.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

In accordance with an embodiment of the present disclosure, a deposition mask includes a mask substrate provided with a cell opening, and a membrane disposed on the mask substrate and provided with pixel openings connected to the cell opening. In such an embodiment, the membrane includes a first electrode film disposed on the mask substrate, a piezoelectric material film disposed on the first electrode film, and a second electrode film disposed on the piezoelectric material film.

In accordance with some embodiments of the present disclosure, the first electrode film may define a first contact hole, the piezoelectric material film may define a second contact hole disposed in the first contact hole, and the second electrode film may include a contact pad disposed in the second contact hole.

In accordance with some embodiments of the present disclosure, the mask substrate may be provided with a contact opening exposing a portion of the first electrode film and the contact pad.

In accordance with some embodiments of the present disclosure, the deposition mask may further include a buffer inorganic film disposed between the mask substrate and the membrane. In such embodiments, the buffer inorganic film may define a first buffer opening connected to the cell opening and a second buffer opening connected to the contact opening.

In accordance with some embodiments of the present disclosure, the deposition mask may further include a reinforcement film disposed on the second electrode film and the contact pad.

In accordance with some embodiments of the present disclosure, the deposition mask may further include a reinforcement film disposed on the membrane. In such embodiments, the reinforcement film may define second pixel openings respectively connected to the pixel openings.

In accordance with some embodiments of the present disclosure, the deposition mask may further include a mask alignment key arranged on the mask substrate.

In accordance with some embodiments of the present disclosure, the membrane may be provided with a key opening, and the mask alignment key may be disposed in the key opening.

In accordance with some embodiments of the present disclosure, the deposition mask may further include a reinforcement film disposed on the membrane, the key opening, and the mask alignment key.

In accordance with some embodiments of the present disclosure, the mask alignment key may include a first alignment key including a same material as the first electrode film, a second alignment key disposed on the first alignment key and including a same material as the piezoelectric material film, and a third alignment key disposed on the second alignment key and including a same material as the second electrode film.

In accordance with another embodiment of the present disclosure, a method of manufacturing a deposition mask includes forming a membrane on a mask substrate, forming pixel openings through the mask substrate, and forming a cell opening connected to the pixel openings through the mask substrate. In such an embodiment, the membrane includes a first electrode film disposed on the mask substrate, a piezoelectric material film disposed on the first electrode film, and a second electrode film disposed on the piezoelectric material film.

In accordance with some embodiments of the present disclosure, the forming of the membrane may include forming the first electrode film on the mask substrate, forming a first contact hole through the first electrode film, forming the piezoelectric material film on the first electrode film and the first contact hole, forming a second contact hole through the piezoelectric material film in the first contact hole, and forming the second electrode film on the piezoelectric material film and the second contact hole.

In accordance with some embodiments of the present disclosure, the method may further include forming a contact opening through the mask substrate. In such embodiments, the contact opening may be formed to expose a portion of the first electrode film and a portion of the second electrode film formed in the second contact hole.

In accordance with some embodiments of the present disclosure, the method may further include forming a buffer inorganic film on the mask substrate, and forming a first buffer opening and a second buffer opening through the buffer inorganic film on the cell opening and the contact opening.

In accordance with some embodiments of the present disclosure, the method may further include forming a reinforcement film on the second electrode film.

In accordance with some embodiments of the present disclosure, the method may further include forming a reinforcement film on the membrane, and forming second pixel openings through the reinforcement film. In such embodiments, the second pixel openings may be respectively connected to the pixel openings.

In accordance with some embodiments of the present disclosure, the method may further include patterning the membrane to form a mask alignment key and a key opening surrounding the mask alignment key on the mask substrate.

In accordance with some embodiments of the present disclosure, the method may further include forming a reinforcement film on the membrane, the key opening, and the mask alignment key.

In accordance with still another embodiment of the present disclosure, an electronic device includes a display panel. In such an embodiment, the display panel includes a backplane substrate, and a plurality of light emitting layers formed on the backplane substrate by using a deposition mask. In such an embodiment, the deposition mask includes a mask substrate provided with a cell opening, and a membrane disposed on the mask substrate and provided with pixel openings connected to the cell opening. In such an embodiment, the membrane includes a first electrode film disposed on the mask substrate, a piezoelectric material film disposed on the first electrode film, and a second electrode film disposed on the piezoelectric material film, and the plurality of light emitting layers may be formed by a deposition process which provides a vapor deposition material through the cell opening and the pixel openings.

In accordance with some embodiments of the present disclosure, the electronic device may further include at least one selected from a processor, a memory, and a power module.

According to embodiments, the membrane may include a first electrode film, a piezoelectric material film, and a second electrode film. In such embodiments, a driving voltage is applied to the first electrode film and the second electrode film in a deposition process for forming light emitting layers, such that a tensile force may be applied to the membrane in the horizontal direction due to a converse piezoelectric effect. Accordingly, sagging of a deposition mask and mask cell regions due to their own weights may be reduced. As a result, the pixel position accuracy (PPA) and the size uniformity of the light emitting layers formed on a backplane substrate may be improved.

### BRIEF DESCRIPTION OF THE DRAWINGS

The above and other features of embodiments of the present disclosure will become more apparent by describing in detail embodiments thereof with reference to the accompanying drawings, in which:

FIG. 1 is a block diagram of an electronic device according to an embodiment of the present disclosure;

FIG. 2 is a schematic diagram of an electronic device according to various embodiments of the present disclosure;

FIG. 3 is an exploded perspective view illustrating a display device according to an embodiment of the present disclosure;

FIG. 4 is a block diagram illustrating the display device shown in FIG. 3;

FIG. 5 is an equivalent circuit diagram illustrating an example of a first sub-pixel shown in FIG. 4;

FIG. 6 is a schematic plan view illustrating an example of a display panel shown in FIG. 3;

FIG. 7 is a schematic enlarged plan view illustrating an example of a display area shown in FIG. 6;

FIG. 8 is a schematic enlarged plan view illustrating another example of the display area shown in FIG. 6;

FIG. 9 is a schematic cross-sectional view illustrating an example of the display panel taken along line I1-I1' shown in FIG. 7;

FIG. 10 is a schematic cross-sectional view illustrating another example of the display panel taken along line I1-I1' shown in FIG. 7;

FIG. 11 is a schematic cross-sectional view illustrating still another example of the display panel taken along line I1-I1' shown in FIG. 7;

FIG. 12 is a schematic perspective view illustrating an example of a head mounted display;

FIG. 13 is a schematic exploded perspective view illustrating the head mounted display shown in FIG. 12;

FIG. 14 is a schematic perspective view illustrating another example of a head mounted display;

FIG. 15 is a schematic diagram illustrating a deposition mask and a deposition apparatus including the deposition mask according to an embodiment;

FIG. 16 is a schematic bottom view illustrating a backplane substrate shown in FIG. 15;

FIG. 17 is a schematic plan view illustrating a deposition mask shown in FIG. 15;

FIG. 18 is a schematic plan view illustrating mask cell regions shown in FIG. 17;

FIG. 19 is a schematic cross-sectional view taken along line I2-I2' shown in FIG. 18;

FIG. 20 is a schematic plan view illustrating a mask chuck and a power supply unit according to an embodiment;

FIG. 21 is a schematic enlarged cross-sectional view illustrating electrical connection between a power supply unit and a membrane;

FIG. 22 is a schematic enlarged cross-sectional view illustrating a contact pad shown in FIG. 21;

FIG. 23 is a schematic cross-sectional view illustrating a mask alignment key shown in FIG. 17;

FIG. 24 is a schematic cross-sectional view illustrating another example of the deposition mask shown in FIG. 15;

FIGS. 25 and 26 are schematic cross-sectional views illustrating a reinforcement film shown in FIG. 24; and

FIGS. 27-38 are schematic cross-sectional views illustrating a method of manufacturing a deposition mask according to an embodiment of the present disclosure.

### DETAILED DESCRIPTION

The invention will now be described more fully hereinafter with reference to the accompanying drawings, in which various embodiments of the disclosure are shown. This invention may, however, be embodied in different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will also be understood that when an element or a layer is referred to as being "on" another element or layer, it can be directly on the other element or layer, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

The display device according to an embodiment of the present disclosure can be applied to various electronic devices. The electronic device according to an embodiment of the present disclosure includes the display device described above, and may further include modules or devices having additional functions in addition to the display device.

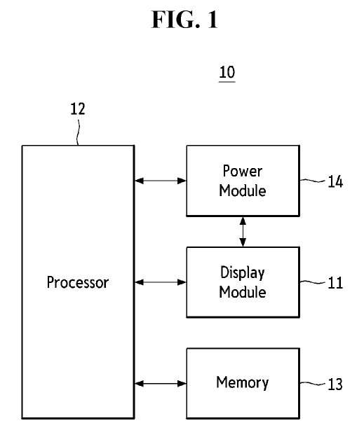

FIG. 1 is a block diagram of an electronic device according to an embodiment of the present disclosure.

Referring to FIG. 1, the electronic device 10 according to an embodiment of the present disclosure may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information used for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power used for the operation of the electronic device 10.

At least one of the components of the electronic device 10 according to an embodiment of the present disclosure may be included in the display device 20 according to the embodiments of the present disclosure. In addition, some modules of the individual modules functionally included in one module may be included in the display device 20, and other modules may be provided separately from the display device 10. In an embodiment, for example, the display device 20 may include the display module 11, and the processor 12, the memory 13, and the power module 14 may be provided in the form of other devices within the electronic device 10 other than the display device 20.

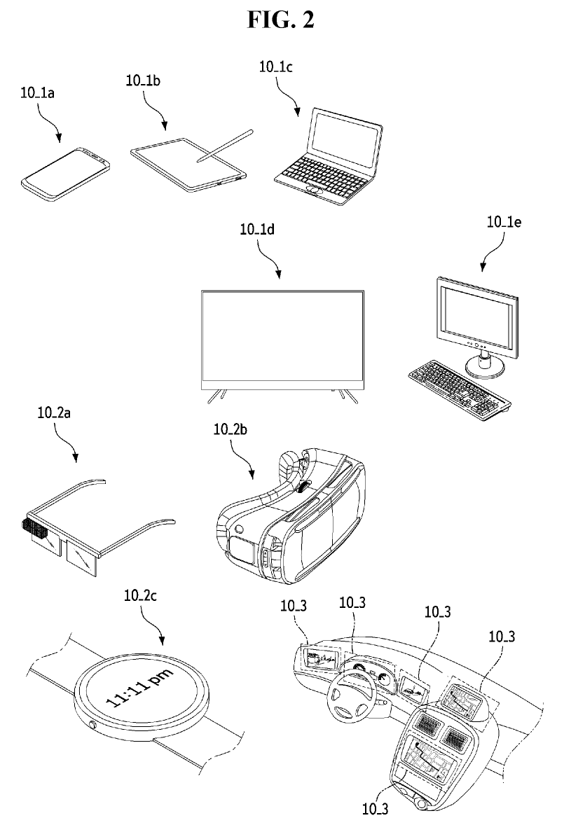

FIG. 2 is a schematic diagram of an electronic device according to various embodiments of the present disclosure.

Referring to FIG. 2, various electronic devices to which display devices 20 according to embodiments of the present disclosure are applied may include not only image display electronic devices such as a smart phone 10_1a, a tablet personal computer (PC) 10_1b, a laptop computer 10_1c, a television (TV) 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a center information display (CID) and a room mirror display arranged on a dashboard, center fascia, and dashboard of an automobile.

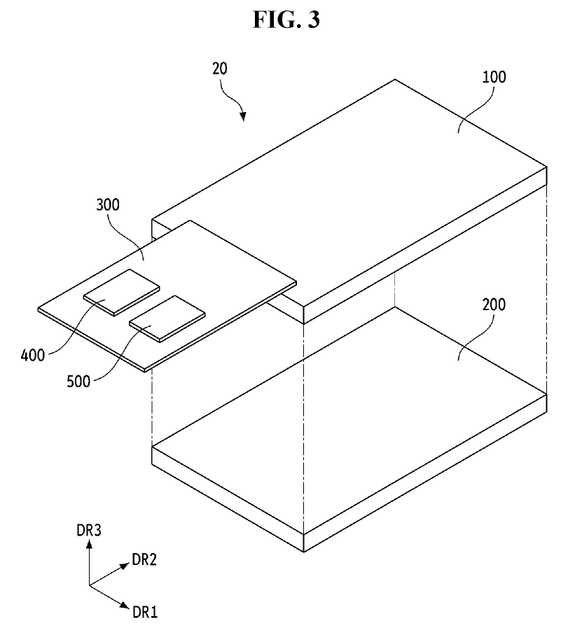

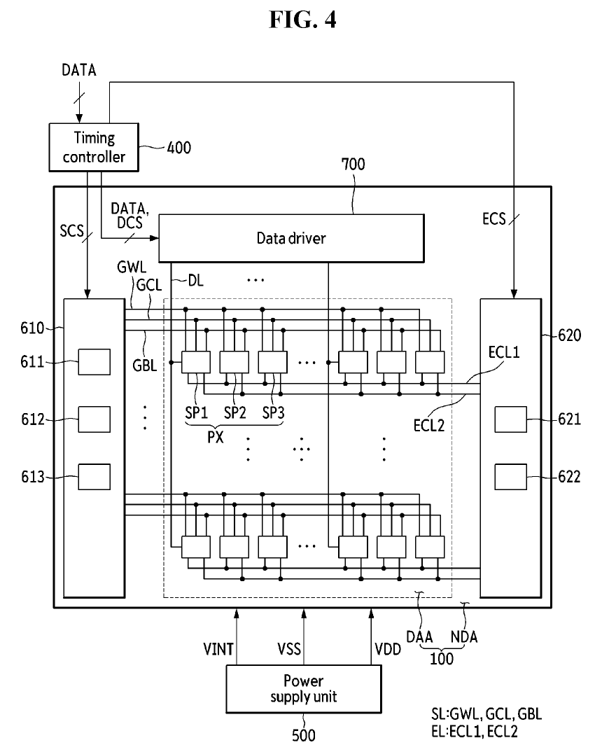

FIG. 3 is an exploded perspective view illustrating a display device according to an embodiment of the present disclosure. FIG. 4 is a block diagram illustrating the display device shown in FIG. 3.

Referring to FIGS. 3 and 4, a display device 20 according to an embodiment may be a device displaying a moving image or a still image. A display device 20 according to an embodiment may be used as the electronic device 10 or the display module 11 of the electronic device 10. In an embodiment, for example, the display device 20 according to an embodiment may be applied to portable electronic devices 10 such as a mobile phone, a smartphone, a tablet personal computer, a mobile communication terminal, an electronic organizer, an electronic book, a portable multimedia player (PMP), a navigation system, an ultra mobile PC (UMPC), and the like. The display device 20 according to an embodiment may be applied as a display module 11 of electronic devices 10 such as a television, a laptop, a monitor, a billboard, or an Internet-of-Things (IoT) terminal, and the like. The display device 20 according to an embodiment may be applied to electronic devices 10 such as a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400, and a power supply circuit 500.

The display panel 100 may have a planar shape similar to a quadrilateral shape. In an embodiment, for example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the present disclosure is not limited thereto.

In an embodiment, as show in FIG. 4, the display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA for displaying an image and a non-display area NDA in which no image is displayed as shown in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

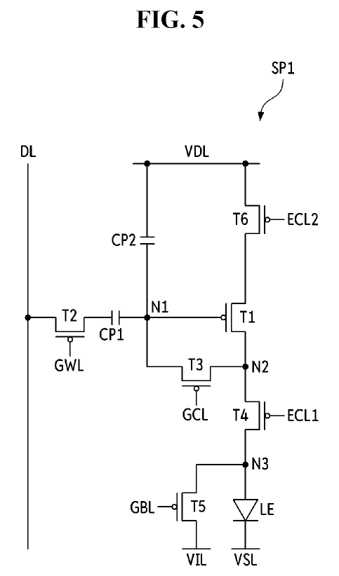

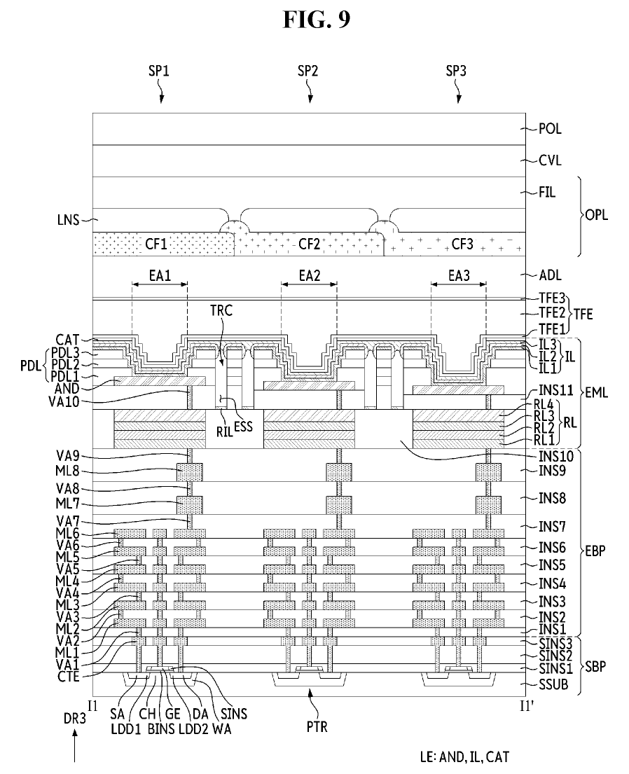

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and disposed on a semiconductor substrate SSUB (see FIG. 9). In an embodiment, for example, the plurality of pixel transistors of the data driver 700 may be formed of complementary metal oxide semiconductor (CMOS), but the present disclosure is not limited thereto.

Each of the plurality of sub-pixels SP1, SP2, and SP3 may be connected to a corresponding one of the plurality of write scan lines GWL, a corresponding of the plurality of control scan lines GCL, a corresponding one of the plurality of bias scan lines GBL, a corresponding one of the plurality of first emission control lines ECL1, a corresponding one of the plurality of second emission control line ECL2, and a corresponding one of the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. In an embodiment, for example, the plurality of scan transistors and the plurality of light emitting transistors may be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and output the write scan signals sequentially to the write scan lines GWL. The control scan signal output unit 612 may generate control scan signals based on the scan timing control signal SCS and sequentially output the control scan signals to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals based on the emission timing control signal ECS and sequentially output the first emission control signals to the first emission control lines ECL1. The second emission control driver 622 may generate second emission control signals based on the emission timing control signal ECS and sequentially output the second emission control signals to the second emission control lines ECL2.

The data driver 700 may include a plurality of data transistors, and the plurality of data transistors may be formed on the semiconductor substrate SSUB (see FIG. 9) through a semiconductor process. In an embodiment, for example, the plurality of data transistors may be formed of CMOS, but the present disclosure is not limited thereto.

The data driver 700 may receive digital video data DATA and a data timing control signal DCS from the timing control circuit 400. The data driver 700 converts the digital video data DATA into analog data voltages based on the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

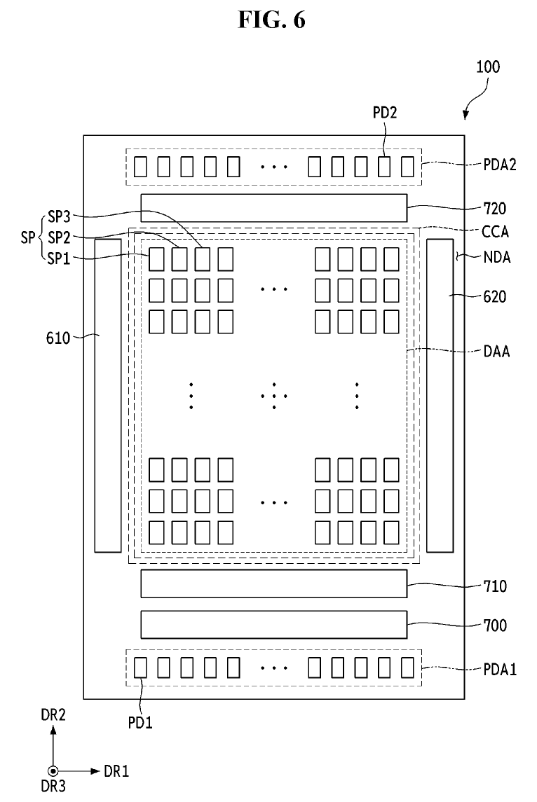

The circuit board 300 may be electrically connected to a plurality of first pads PD1 (see FIG. 6) of a first pad portion PDA1 (see FIG. 6) of the display panel 100 by using a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

In an embodiment, each of the timing control circuit 400 and the power supply circuit 500 may be formed as an integrated circuit (IC) and attached to one surface of the circuit board 300. In such an embodiment, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. In such an embodiment, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. In an embodiment, for example, the plurality of timing transistors and the plurality of power transistors may be formed of CMOS, but the present disclosure is not limited thereto. Each of the timing control circuit 400 and the power supply circuit 500 may be disposed between the data driver 700 and the first pad portion PDA1 (see FIG. 6).

FIG. 5 is an equivalent circuit diagram illustrating an example of a first sub-pixel shown in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In an embodiment, the first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. In an embodiment, for example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as "driving current") flowing between the source electrode and the drain electrode thereof according to a voltage applied to the gate electrode thereof.

A second transistor T2 may be connected between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be connected between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be connected between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed or connected between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). In an embodiment, for example, each of the first to sixth transistors T1 to T6 may be a P-type MOSFET, but the present disclosure is not limited thereto. In another embodiment, for example, each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 5 shows an embodiment where the first sub-pixel SP1 includes six transistors T1 to T6 and two capacitors C1 and C2, it would be understood that the equivalent circuit diagram of the first sub-pixel SP1 is not limited to that shown in FIG. 5. In an embodiment, for example, the number of transistors and the number of capacitors of the first sub-pixel SP1 are not limited to those shown in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, any repetitive detailed description of the equivalent circuit diagram of the second sub-pixel SP2 and the equivalent circuit diagram of the third sub-pixel SP3 is not repeated in the present disclosure.

FIG. 6 is a schematic plan view illustrating an example of a display panel shown in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, for example, the scan driver 610 may be disposed on one side of the display area DAA in the first direction DR1, and the emission driver 620 may be disposed on the other side of the display area DAA in the first direction DR1. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, for example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be disposed on the fourth side of the display area DAA. In an embodiment, for example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. In an embodiment, for example, the first distribution circuit 710 may distribute the data voltages applied through one first pad PD1 of the first pad portion PDA1 to the P data lines DL (P is a positive integer of 2 or greater), and as a result, the number of the plurality of first pads PD1 may be reduced. The first distribution circuit 710 may be disposed on the third side of the display area DAA of the display panel 100. In an embodiment, for example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. In an embodiment, for example, the second distribution circuit 720 may be disposed on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed outside at least one side of the display area DAA. In an embodiment, for example, the cathode connection part CCA may be disposed outside at least on one side among the left side, the right side, the upper side, and the lower side of the display area DAA. Alternatively, the cathode connection part CCA may be disposed to surround the display area DAA as shown in FIG. 6 in order to minimize a deviation in the first driving voltage VSS caused by voltage drop (IR drop) or voltage rise (IR rising) of the second electrode CAT in the display area DAA.

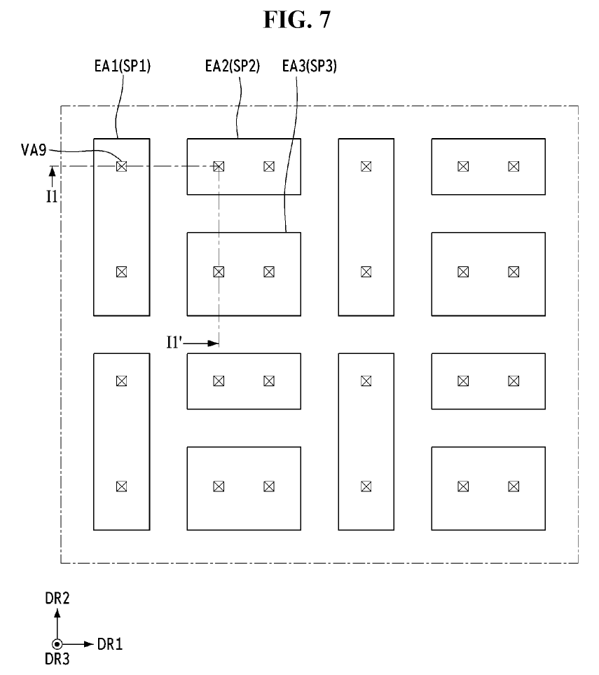

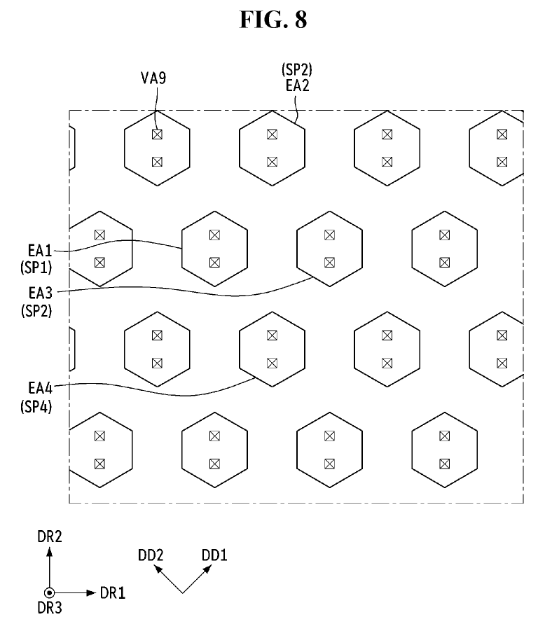

FIG. 7 is a schematic enlarged plan view illustrating an example of a display area shown in FIG. 6. FIG. 8 is a schematic enlarged plan view illustrating another example of the display area shown in FIG. 6.

Referring to FIGS. 7 and 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view(or when viewed in the third direction DR3), a quadrilateral or hexagonal shape as shown in FIGS. 7 and 8, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

In an embodiment, as shown in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

In another embodiment, as shown in FIG. 8, the emission areas EA1, EA2, EA3, and EA4 may have a hexagonal shape in a plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by about 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. In an embodiment, for example, the first light may be light of a blue wavelength band, the second light may be light of a green wavelength band, and the third light may be light of a red wavelength band. In an embodiment, for example, the blue wavelength band may be a wavelength band of light whose main peak wavelength is in a range of about 370 nm to about 460 nm, the green wavelength band may be a wavelength band of light whose main peak wavelength is in a range of about 480 nm to about 560 nm, and the red wavelength band may be a wavelength band of light whose main peak wavelength is in a range of about 600 nm to about 750 nm.

In another embodiment, as shown in FIG. 7, each of the plurality of pixels PX may include three emission areas EA1, EA2, and EA3, or may include four emission areas EA1, EA2, EA3, and EA4 as shown in FIG. 8. In an embodiment, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape.

FIG. 9 is a schematic cross-sectional view illustrating an example of the display panel taken along line I1-I1' shown in FIG. 7.

Referring to FIG. 9, an embodiment of the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an embodiment, for example, where the first type impurity is a p-type impurity, the second type impurity may be an n-type impurity. In another embodiment, for example, where the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to a corresponding one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of silicon carbonitride (SiCN) or a silicon oxide (SiOx)-based inorganic film, but the present disclosure is not limited thereto.

In an embodiment, the semiconductor substrate SSUB may be replaced with a glass substrate or a polymer resin substrate such as polyimide. In such an embodiment, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

In an embodiment, for example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The first to eighth vias VA1 to VA8 may include or be made of substantially a same material as each other. First to eighth interlayer insulating films INS1 to INS8 may include or be formed of a silicon oxide (SiOx)-based inorganic layer, but the present disclosure is not limited thereto.

A ninth interlayer insulating film INS9 may be disposed on the eighth interlayer insulating film INS8 and the eighth conductive layer ML8. The ninth interlayer insulating film INS9 may be formed of a silicon oxide (SiOx)-based inorganic film, but the present disclosure is not limited thereto.

Each of the ninth vias VA9 may penetrate the ninth interlayer insulating film INS9 and be connected to the exposed eighth conductive layer ML8. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

The display element layer EML may be disposed on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be disposed on the ninth interlayer insulating film INS9. Each of the reflective electrodes RL may include at least one reflective electrode RL1, RL2, RL3, and RL4. In an embodiment, for example, each of the reflective electrodes RL may include the first to fourth reflective electrodes RL1, RL2, RL3, and RL4 as shown in FIG. 9.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the first reflective electrodes RL1 may include titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrodes RL.

The tenth interlayer insulating film INS10 and the eleventh interlayer insulating film INS11 may be formed of a silicon oxide (SiOx)-based inorganic film, but the present disclosure is not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

In an embodiment, for example, as shown in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film. Alternatively, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In an embodiment, the first pixel defining film PDL1, the second pixel defining film PDL2, and the third pixel defining film PDL3 may have a cross-sectional structure having a stepped portion such that the likelihood of the first encapsulation inorganic film TFE1 being cut off due to the step coverage may be substantially reduced or effectively prevented. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate or extend through the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed between the neighboring sub-pixels SP1, SP2, and SP3. Although FIG. 9 illustrates an embodiment where two trenches TRC are disposed between the neighboring sub-pixels SP1, SP2, and SP3, the present disclosure is not limited thereto.

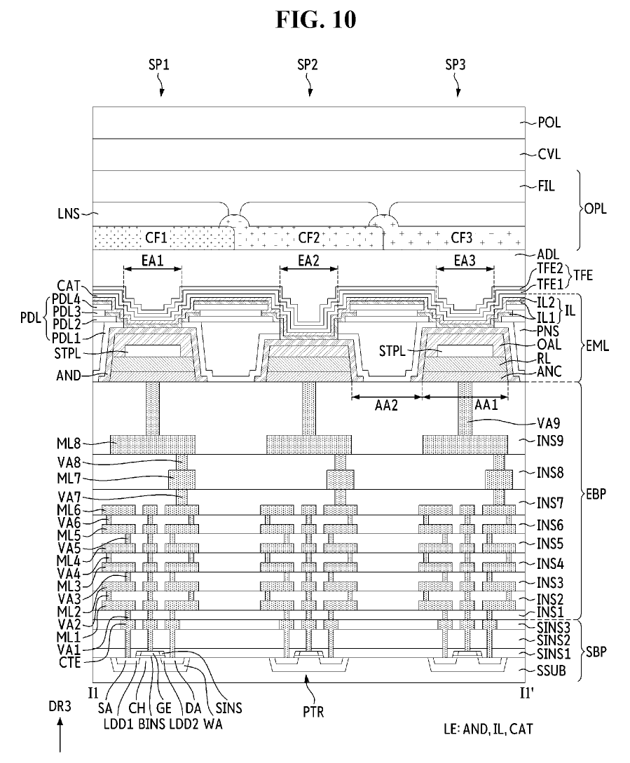

The light emitting stack IL may include a plurality of stack layers IL1, IL2, and IL3. FIG. 9 illustrates an embodiment where the light emitting stack IL has a three-tandem structure including a first stack layer IL1, a second stack layer IL2, and a third stack layer IL3, but the present disclosure is not limited thereto. In another embodiment, for example, the light emitting stack IL may have a two-tandem structure including two stack layers as shown in FIG. 10.

In an embodiment having the three-tandem structure, the light emitting stack IL may have a tandem structure including a plurality of intermediate layers IL1, IL2, and IL3 that emit different lights. In an embodiment, for example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film IL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In an embodiment having the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In an embodiment having the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be disposed on the pixel defining film PDL.

In addition, FIG. 9 illustrates an embodiment where the light emitting stack IL that emits light is disposed in the first emission area EA1, the second emission area EA2, and the third emission area EA3, but the present disclosure is not limited thereto. In another embodiment, for example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light emitting stack IL. That is, the second electrode CAT may be disposed on the third stack layer IL3. The second electrode CAT may be formed of a transparent conductive material (TCO) such as ITO or IZO that can transmit light or a semi-transmissive conductive material such as magnesium (Mg), silver (Ag), or an alloy of Mg and Ag. In an embodiment where the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may be formed of multiple layers (or to have a multilayered structure) in which one or more inorganic films of silicon nitride (SiNx), silicon oxynitride (SiON), silicon oxide (SiOx), titanium oxide (TiOx), and aluminum oxide (AlOx) layers are alternately stacked.

In addition, the encapsulation layer TFE may include at least one organic film TFE2 to protect the display element layer EML from foreign substances such as dust. The encapsulating organic film TFE2 may be disposed between the first encapsulating inorganic film TFE1 and the second encapsulating inorganic film TFE3. The encapsulation organic film TFE2 may be a monomer. Alternatively, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. In an embodiment where the cover layer CVL is a glass substrate, it may be attached onto the filling layer FIL. In such an embodiment, the filling layer FIL may serve to bond the cover layer CVL. In an embodiment where the cover layer CVL is a glass substrate, the cover layer CVL may serve as an encapsulation substrate. In an embodiment where the cover layer CVL is a polymer resin, the cover layer CVL may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. In an embodiment, for example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of the display panel taken along line I1-I1' shown in FIG. 7.

The embodiment of FIG. 10 is substantially the same as the embodiment of FIG. 9 except that the first electrode AND of each of the light emitting elements LE is in contact with and electrically connected to the side surface of a connection electrode ANC connected to the eighth conductive layer ML8, the trench TRC is omitted, and instead, the third pixel defining film PDL3 and a fourth pixel defining film PDL4 have an eave-shaped or mushroom-shaped cross-sectional structure. In description of the embodiment of FIG. 10, any repetitive detailed description of the same or like elements as those described above with reference to FIG. 9 will be omitted.

Referring to FIG. 10, in an embodiment, the plurality of connection electrodes ANC may be respectively disposed on first portions AA1 of the ninth interlayer insulating film INS9. Each of the plurality of connection electrodes ANC may be disposed on the first portion AA1 of the ninth interlayer insulating film INS9 corresponding thereto. A plurality of connection electrodes ANC may include or be formed of at least one selected from copper (Cu), aluminum (Al), tungsten (W), molybdenum (Mo), chromium (Cr), gold (Au), titanium (Ti), nickel (Ni), and neodymium (Nd), a combination (e.g., an alloy) thereof, or a transparent conductive oxide. In an embodiment, for example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, each of the plurality of reflective electrodes RL may include aluminum (Al) having high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may be formed of a silicon oxide (SiOx)-based inorganic film, but the present disclosure is not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thicknesses of the optical auxiliary film OAL in the first emission area EA1, the second emission area EA2, and the third emission area EA3 may be substantially the same as each other.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary layer OAL are sequentially stacked, the first electrode AND of each of the light emitting elements LE may be disposed on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating (defined or formed through) the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same as each other.

Alternatively, the thickness of the first portion AA1 of the ninth interlayer insulating film INS9 may be greater than the thickness of the second portion AA2 thereof. In this case, the side surface of the first portion AA1 of the ninth interlayer insulating film INS9 may be exposed, and the first electrode AND of each of the light emitting elements LE may be disposed on the exposed side surface of the first portion AA1 of the ninth interlayer insulating film INS9.

The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), a combination (e.g., an alloy) thereof, or a transparent conductive oxide. For example, the first electrode AND of each of the light emitting elements LE may include titanium (Ti), titanium nitride (TiN), indium tin oxide (ITO), or indium zinc oxide (IZO), but the present disclosure is limited thereto.

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. In an embodiment, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth interlayer insulating film INS9.

The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In an embodiment, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may be formed of a silicon nitride (SiNx)-based inorganic film, whereas the second pixel defining film PDL2, the fourth pixel defining film PDL4, and the planarization film PNS may be formed of a silicon oxide (SiOx)-based inorganic film. The first pixel defining film PDL1 is formed of a material different from that of the planarization film PNS, and thus may serve as a stopper in a chemical mechanical polishing process for the planarization film PNS.

In an embodiment where the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an eaves-shaped or mushroom-shaped cross-sectional structure.

The light emitting stack IL may be disposed on the first electrode AND and the pixel defining film PDL. The light emitting stack IL may include the first stack layer IL1 and the second stack layer IL2 that emit different lights. In an embodiment where the light emitting stack IL has a two-tandem structure, one of the first stack layer IL1 and the second stack layer IL2 may emit light that includes the wavelength range of one of the first light, the second light, and the third light, and the other may emit light that includes the wavelength ranges of the other two lights. In an embodiment, for example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates an embodiment where the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to prevent the light emitting stack IL in the adjacent emission areas EA1, EA2, and EA3 from emitting light other than the originally intended light due to the influence of the above current.

Although FIG. 10 illustrates an embodiment having a two-tandem structure in which the light emitting stack IL includes two stack layers IL1 and IL2, the present disclosure is not limited thereto. In an embodiment, for example, the light emitting stack IL may have a three-tandem structure including three stack layers as shown in FIG. 9. In such an embodiment, it may be designed such that the charge generation layer between the first stack layer IL1 and the second stack layer IL2, and the charge generation layer between the second stack layer IL2 and the third stack layer IL3 may be cut off by adjusting the height of the third pixel defining film PDL3. Alternatively, as shown in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but the present disclosure is not limited thereto.

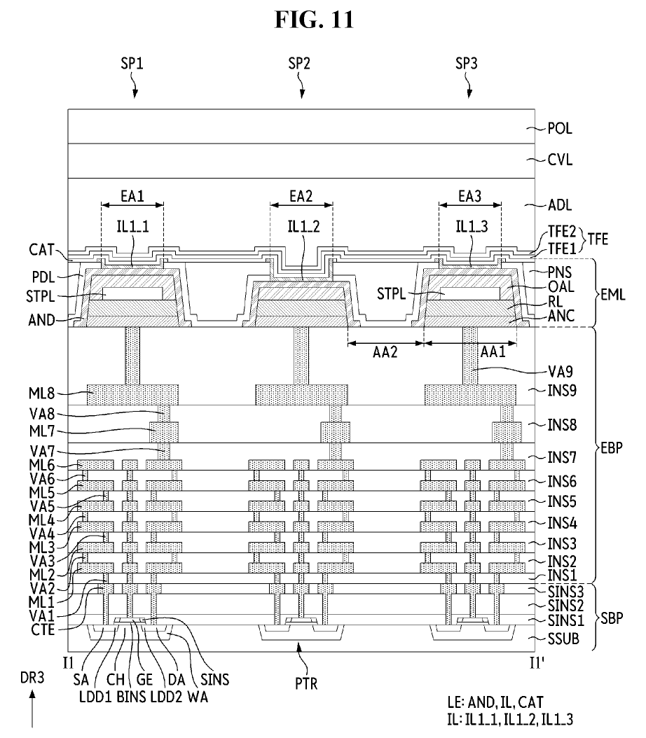

FIG. 11 is a schematic cross-sectional view illustrating still another example of the display panel taken along line I1-I1' shown in FIG. 7.

The embodiment of FIG. 11 is substantially the same as the embodiment of FIG. 10 except that the light emitting elements LE have a single stack structure. In description of the embodiment of FIG. 11, any repetitive detailed description of the same or like elements as those described above with reference to FIG. 10 will be omitted.

Referring to FIG. 11, in an embodiment, the pixel defining film PDL may be disposed on the ninth interlayer insulating film INS9 and the first electrodes AND, and the planarization film PNS may be disposed on the pixel defining film PDL. The planarization film PNS and the pixel defining film PDL may be provided with openings exposing the first electrodes AND, and light emitting stack IL may be disposed on the first electrodes AND. In an embodiment, for example, the pixel defining film PDL may be provided with openings exposing the first electrodes AND in the first light emission area EA1, the second light emission area EA2 and the third light emission area EA3, and the planarization film PNS may be provided with an opening exposing the first electrode AND in the second light emission area EA2. In an embodiment, for example, the light emitting stack IL may include a first stack layer IL1_1, a second stack layer IL1_2, and a third stack layer IL1_3.

The first stack layer IL1_1 may be disposed on the first electrode AND exposed by the pixel defining film PDL in the first light emission area EA1. The first stack layer IL1_1 may also be disposed on a portion of the pixel defining film PDL. In an embodiment, for example, the first stack layer IL1_1 may include a hole injecting layer, a hole transporting layer, a first light emitting layer, an electron transporting layer, and an electron injecting layer.

The second stack layer IL1_2 may be disposed on the first electrode AND exposed by the planarization film PNS and the pixel defining film PDL in the second light emission area EA2. The second stack layer IL1_2 may also be disposed on a portion of the planarization film PNS. In an embodiment, for example, the second stack layer IL1_2 may include the hole injecting layer, the hole transporting layer, a second light emitting layer, the electron transporting layer, and the electron injecting layer.

The third stack layer IL1_3 may be disposed on the first electrode AND exposed by the pixel defining film PDL in the third light emission area EA3. The third stack layer IL1_3 may also be disposed on a portion of the pixel defining film PDL. In an embodiment, for example, the third stack layer IL1_3 may include the hole injecting layer, the hole transporting layer, a third light emitting layer, the electron transporting layer, and the electron injecting layer.

In such an embodiment, the first stack layer IL1_1, the second stack layer IL1_2, and the third stack layer IL1_3 may be spaced apart from each other, and thus the second to fourth pixel defining films PDL2, PDL3 and PDL4 used to separate the light emitting stack IL in the embodiment of FIG. 10 may be omitted.

In such an embodiment, the first stack IL1_1 of the first light emission area EA1 may emit first light, the second stack layer IL1_2 of the second light emission area EA2 may emit second light, and the third stack layer IL1_3 of the third light emission area EA3 may emit third light. Accordingly, the first to third color filters CF1, CF2 and CF3 of the optical layer OPL used in the embodiment of FIG. 9, the plurality of lenses LNS, and the filling layer FIL may be omitted.

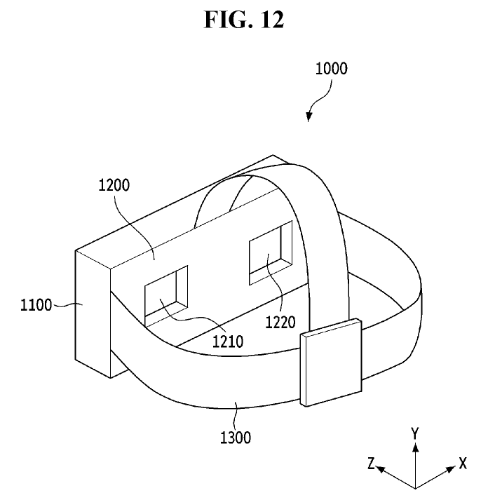

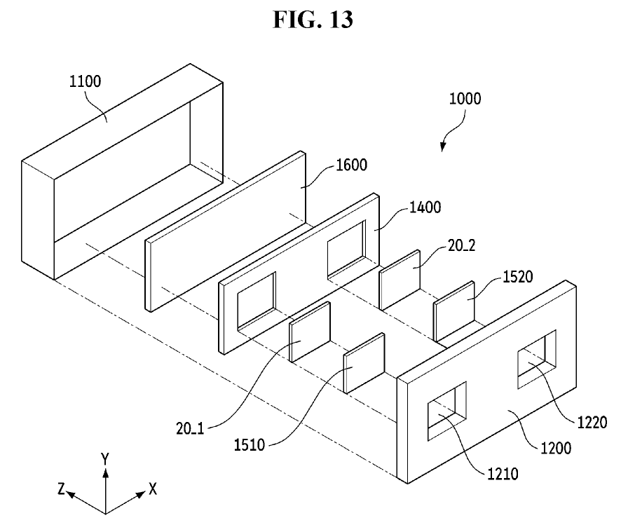

FIG. 12 is a schematic perspective view illustrating one example of a head mounted display. FIG. 13 is a schematic exploded perspective view illustrating the head mounted display shown in FIG. 12.

Referring to FIGS. 12 and 13, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 11, any repetitive detailed description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data, and transmit the digital video data to the first display device 20_1 and the second display device 20_2 through the connector.

The control circuit board 1600 may transmit the digital video data corresponding to a left-eye image optimized for the user's left eye to the first display device 20_1, and may transmit the digital video data corresponding to a right-eye image optimized for the user's right eye to the second display device 20_2. Alternatively, the control circuit board 1600 may transmit the same digital video data to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 12 and 13 illustrate an embodiment where the first eyepiece 1210 and the second eyepiece 1220 are disposed separately, but the present disclosure is not limited thereto. In another embodiment, the first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

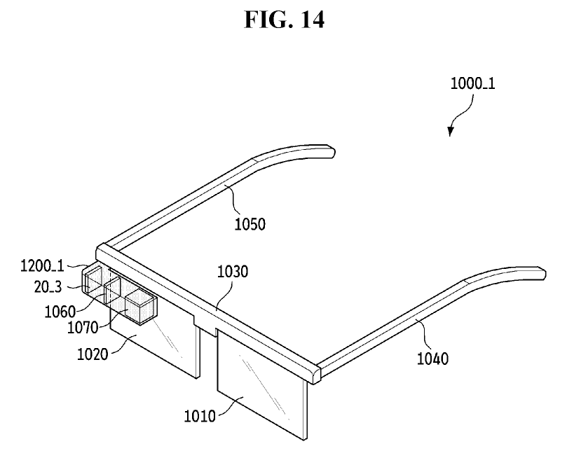

The head mounted band 1300 serves to secure the display device housing 1100 to the user's head such that the first eyepiece 1210 and the second eyepiece 1220 of the housing cover 1200 remain located on the user's left and right eyes, respectively. In an embodiment where the display device housing 1200 is desired to be implemented to be lightweight and compact, the head mounted display 1000 may be provided with, as shown in FIG. 14, an eyeglass frame instead of the head mounted band 1300.

FIG. 14 is a schematic perspective view illustrating another example of a head mounted display.

Referring to FIG. 14, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 14 illustrates an embodiment where the display device housing 1200_1 is disposed at the right end of the support frame 1030, but the present disclosure is not limited thereto. In another embodiment, for example, the display device housing 1200_1 may be disposed at the left end of the support frame 1030, and in such an embodiment, the image of the display device 20_3 may be provided to the user's left eye. Alternatively, the display device housing 1200_1 may be disposed at both the left and right ends of the support frame 1030, and in this case, the user may view the image displayed on the display device 20_3 through both the left and right eyes.

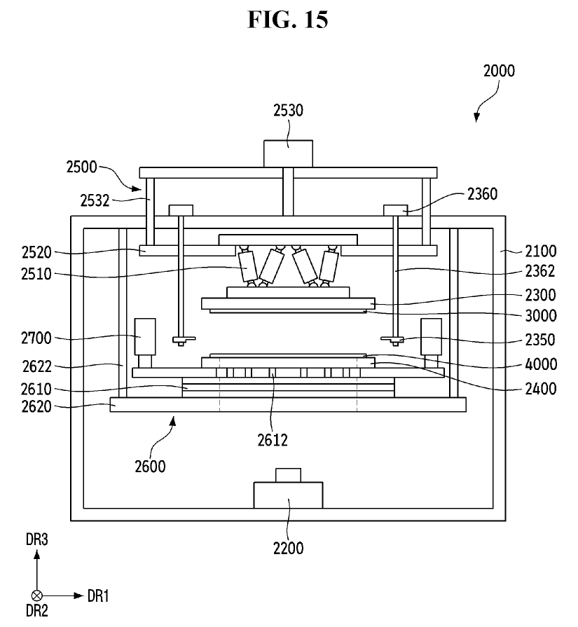

FIG. 15 is a schematic diagram illustrating a deposition mask and a deposition apparatus including the deposition mask according to an embodiment.

Referring to FIG. 15, a deposition apparatus 2000 according to an embodiment may be used to form a deposition material layer on a substrate. For example, the deposition apparatus 2000 according to an embodiment may be used to form light emitting layers on a backplane substrate 3000 (or display substrate) in a manufacturing process of the display panel 100 (see FIG. 3). In an embodiment, for example, as shown in FIG. 11, the semiconductor backplane SBP and the light emitting element backplane EBP may be disposed on the backplane substrate 3000, and electrode patterns, e.g., the first electrodes AND functioning as anode electrodes, may be disposed on the light emitting element backplane EBP. In addition, the pixel defining film PDL provided with openings that expose the first electrodes AND may be disposed on the light emitting element backplane EBP. In an embodiment, for example, the deposition apparatus 2000 may form first light emitting layers on the first electrodes AND of the first emission areas EA1. As another example, the deposition apparatus 2000 may form second light emitting layers on the first electrodes AND of the second emission areas EA2. In another embodiment, for example, the deposition apparatus 2000 may form third light emitting layers on the first electrodes AND of the third emission areas EA3.

The deposition apparatus 2000 may include a deposition source 2200 for providing a vapor deposition material on the backplane substrate 3000, a substrate chuck 2300 for supporting the backplane substrate 3000 to face the deposition source 2200, and a mask chuck 2400 disposed between the deposition source 2200 and the substrate chuck 2300 to support a deposition mask 4000 to face the backplane substrate 3000. The deposition source 2200, the substrate chuck 2300, and the mask chuck 2400 may be disposed in a process chamber (or an evaporation chamber) 2100.

The process chamber 2100 may have or define an internal space, and a deposition process for forming a deposition material layer on the backplane substrate 3000 may be performed in the internal space of the process chamber 2100. The process chamber 2100 may be connected to a vacuum pump (not shown), and a vacuum atmosphere may be created in the internal space of the process chamber 2100 by the vacuum pump. An opening (not shown) for loading/unloading of the backplane substrate 3000 and the deposition mask 4000 may be provided on one wall of the process chamber 2100, and the opening may be opened and closed by a gate valve (not shown).

The deposition source 2200 may be disposed in the process chamber 2100, and a deposition material may be stored in the deposition source 2200. The deposition source 2200 may evaporate a deposition material such as an organic material, an inorganic material, a conductive material, or the like toward the backplane substrate 3000, and the evaporated deposition material may be deposited on the backplane substrate 3000 through the deposition mask 4000. In an embodiment, for example, the deposition source 2200 may evaporate an organic light emitting material for forming light emitting layers on the backplane substrate 3000, and may be provided with a heater (not shown) for evaporating the organic light emitting material. The evaporated organic light emitting material may be deposited on electrode patterns on the backplane substrate 3000 through the deposition mask 4000, thereby forming light emitting layers on the electrode patterns of the backplane substrate 3000. In an embodiment, as shown in FIG. 15, the deposition source 2200 may be disposed on the central portion of the bottom surface of the process chamber 2100, but the deposition source 2200 may be configured to move horizontally by a separate driver (not shown).

The substrate chuck 2300 may be disposed above the deposition source 2200 and may support the backplane substrate 3000 such that the backplane substrate 3000 faces the deposition source 2200. In an embodiment, for example, the substrate chuck 2300 may be an electrostatic chuck that holds the rear surface of the backplane substrate 3000 using an electrostatic force. In such an embodiment, the electrode patterns, e.g., first electrodes AND, may be disposed on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2350 for loading the backplane substrate 3000 onto the substrate chuck 2300 may be arranged in the process chamber 2100. The lift fingers 2350 may be arranged around the substrate chuck 2300 and the mask chuck 2400, and may be respectively moved vertically by finger drivers 2360. In an embodiment, for example, three or four lift fingers 2350 may be arranged around the substrate chuck 2300 and the mask chuck 2400, and may be moved in the third direction DR3 by the finger drivers 2360.

The backplane substrate 3000 may be loaded into the process chamber 2100 by a transfer robot (not shown), and may be transferred from the transfer robot onto the lift fingers 2350 under the substrate chuck 2300. In this case, the rear surface of the backplane substrate 3000 may face the bottom surface of the substrate chuck 2300, and the lift fingers 2350 may support the front edge portions of the backplane substrate 3000. The finger drivers 2360 may raise the lift fingers 2350 such that the backplane substrate 3000 becomes adjacent to the bottom surface of the substrate chuck 2300, and the rear surface of the backplane substrate 3000 may be held on the bottom surface of the substrate chuck 2300 by an electrostatic force.

The finger drivers 2360 may be arranged on the upper lid of the process chamber 2100 and may be respectively connected to the lift fingers 2350 through driving shafts 2362 that extend vertically through the upper lid of the process chamber 2100. The finger drivers 2360 may vertically move the lift fingers 2350 to load or unload the backplane substrate 3000. In addition, the finger drivers 2360 may rotate the lift fingers 2350 with respect to each of the driving shafts 2362. In an embodiment, for example, the finger drivers 2360 may rotate the lift fingers 2350 such that the ends of the lift fingers 2350 do not overlap the substrate chuck 2300 and the mask chuck 2400, thereby enabling vertical movement of the lift fingers 2350. In addition, the finger drivers 2360 may rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot, and may be transferred onto the lift fingers 2350 above the mask chuck 2400. The edge portions of the deposition mask 4000 may be placed on the ends of the lift fingers 2350, and the finger drivers 2360 may lower the lift fingers 2350 to load the deposition mask 4000 onto the mask chuck 2400. In this case, recesses (not shown) into which ends of lift fingers 2350 are inserted may be provided at the edge portions of the mask chuck 2400, and the finger drivers 2360 may rotate the lift fingers 2350 such that the lift fingers 2350 do not overlap the mask chuck 2400 after the deposition mask 4000 is loaded on the mask chuck 2400.

The mask chuck 2400 may support the edge portion of the deposition mask 4000. In an embodiment, for example, the mask chuck 2400 may be an electrostatic chuck configured to hold the edge portion of the deposition mask 4000 using an electrostatic force. In particular, the mask chuck 2400 may be provided with a circular opening to expose the deposition mask 4000 toward the deposition source 2200. In an embodiment, for example, the mask chuck 2400 may have a disk shape or a quadrilateral plate shape with a circular opening.

The deposition apparatus 2000 may include a chuck driver for adjusting the position and posture of the backplane substrate 3000 and the deposition mask 4000. In an embodiment, for example, the deposition apparatus 2000 may include a substrate chuck driver 2500 for moving the substrate chuck 2300 and a mask chuck driver 2600 for moving the mask chuck 2400.

The substrate chuck driver 2500 may move the substrate chuck 2300 in the first direction DR1, the second direction DR2, and the third direction DR3 to adjust the position of the backplane substrate 3000. In this case, the first direction DR1 may be the first horizontal direction, the second direction DR2 may be the second horizontal direction perpendicular to the first direction DR1, and the third direction DR3 may be the vertical direction. For example, the first direction DR1, the second direction DR2, and the third direction DR3 may be an X-axis direction, a Y-axis direction, and a Z-axis direction, respectively.

The substrate chuck driver 2500 may rotate the substrate chuck 2300 around the Z-axis to adjust the azimuth of the backplane substrate 3000, that is, the angle at which the backplane substrate 3000 is held on the bottom surface of the substrate chuck 2300. Further, the substrate chuck driver 2500 may rotate the substrate chuck 2300 around the X-axis, and may also rotate the substrate chuck 2300 around the Y-axis in order to adjust the inclination of the backplane substrate 3000. In an embodiment, for example, the substrate chuck driver 2500 may include a hexapod actuator 2510 that provides a motion of six degrees of freedom (X, Y, Z, θx, θy, and θz).

The substrate chuck driver 2500 may include a substrate stage 2520 on which the hexapod actuator 2510 is mounted, and a second actuator 2530 connected to the substrate stage 2520. The substrate stage 2520 may be disposed horizontally in the process chamber 2100, and the second actuator 2530 may be disposed above the process chamber 2100. The second actuator 2530 may be connected to the substrate stage 2520 by a plurality of driving shafts 2532 extending in the third direction DR3, i.e., the vertical direction (Z-axis direction) through the upper lid of the process chamber 2100, and may move the substrate stage 2520 in the central axis direction of the hexapod actuator 2510, i.e., the vertical direction. In an embodiment, for example, the second actuator 2530 may be configured using a brushless direct current (DC) motor, a linear motor, a direct drive (DD) motor, or the like, and may adjust the height of the substrate chuck 2300 for loading or unloading the backplane substrate 3000.

The hexapod actuator 2510 may include a first platform connected to the substrate chuck 2300, a second platform mounted on the substrate stage 2520, and six sub-actuators disposed between the first platform and the second platform. In an embodiment, for example, the six sub-actuators may each be configured using a brushless DC motor, a voice coil linear motor, a step motor, DD motor, a servo motor, or the like, and may move and rotate the first platform to adjust the horizontal position, vertical position, azimuth, and inclination of the backplane substrate 3000.

The mask chuck driver 2600 may move and rotate the mask chuck 2400 to adjust the horizontal position of the deposition mask 4000 and the azimuth angle of the deposition mask 4000, that is, the angle at which the deposition mask 4000 is placed on the mask chuck 2400. The mask chuck driver 2600 may move the mask chuck 2400 in a direction parallel to the deposition mask 4000 and rotate the mask chuck 2400 with respect to the central axis of the mask chuck 2400. For example, the mask chuck driver 2600 may move the mask chuck 2400 in the first direction DR1 (X-axis) and the second direction DR2 (Y-axis), and may rotate the mask chuck 2400 with respect to the third direction DR3 (Z-axis).

The mask chuck driver 2600 may include, e.g., a piezo actuator 2610 that provides a motion of three degrees of freedom (X, Y, and θz). The piezo actuator 2610 may be provided with (or define) an opening communicating with the circular opening of the mask chuck 2400. The mask chuck 2400 may be spaced upward from the piezo actuator 2610 by a predetermined distance. For example, a plurality of support members 2612 may be arranged on the piezo actuator 2610, and the mask chuck 2400 may be disposed on the plurality of support members 2612.

The mask chuck driver 2600 may include a mask stage 2620 that is horizontally disposed in the process chamber 2100 and supports the piezo actuator 2610. In an embodiment, for example, the mask stage 2620 may be provided with an opening that communicates with the opening of the piezo actuator 2610 and may be supported by a plurality of posts 2622 that are connected to the upper lid of the process chamber 2100.

After the backplane substrate 3000 and the deposition mask 4000 are loaded onto the substrate chuck 2300 and the mask chuck 2400, respectively, the second actuator 2530 may lower the substrate chuck 2300 such that the backplane substrate 3000 is brought adjacent to the deposition mask 4000. The hexapod actuator 2510 may adjust the gap between the backplane substrate 3000 and the deposition mask 4000, and may adjust the inclination of the substrate chuck 2300 to adjust the parallelism between the substrate chuck 2300 and the mask chuck 2400. In an embodiment, for example, although not shown, a plurality of gap sensors (not shown) for measuring the gap between the substrate chuck 2300 and the mask chuck 2400 may be mounted on the substrate chuck 2300, and the hexapod actuator 2510 may adjust the parallelism between the substrate chuck 2300 and the mask chuck 2400 based on the measured values of the gap sensors.

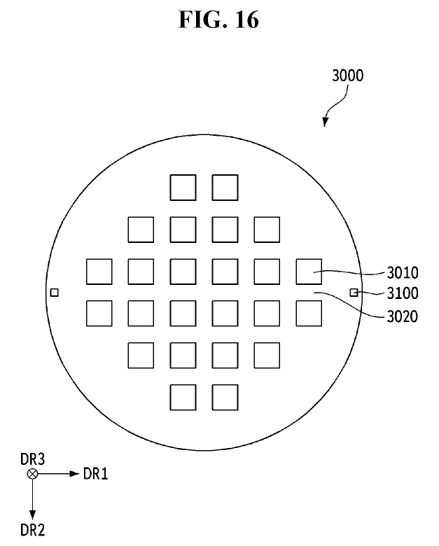

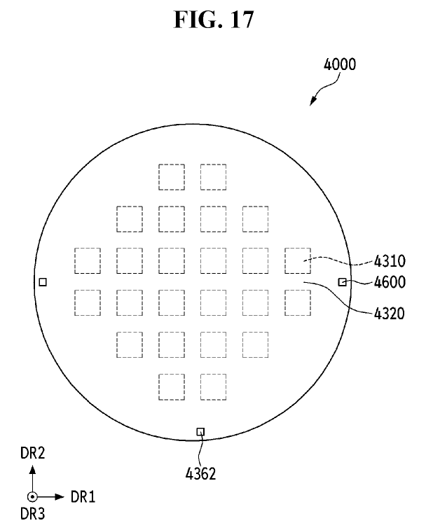

The deposition apparatus 2000 may include cameras 2700 for acquiring positional information of the backplane substrate 3000 and the deposition mask 4000 for alignment between the backplane substrate 3000 and the deposition mask 4000. In an embodiment, for example, substrate alignment keys 3100 (see FIG. 16) may be arranged on the edge portions of the backplane substrate 3000, and mask alignment keys 4600 (see FIG. 17) may be arranged on the edge portions of the deposition mask 4000. The deposition apparatus 2000 may include the cameras 2700 for detecting the substrate alignment keys 3100 and the mask alignment keys 4600, and the substrate chuck driver 2500 or the mask chuck driver 2600 may align the backplane substrate 3000 and the deposition mask 4000 with each other based on the positional information of the substrate alignment keys 3100 and the mask alignment keys 4600 obtained by the cameras 2700.

After the parallelism adjustment between the substrate chuck 2300 and the mask chuck 2400 and the positional alignment between the backplane substrate 3000 and the deposition mask 4000 are performed as described above, the backplane substrate 3000 may be positioned on the deposition mask 4000. In an embodiment, for example, the hexapod actuator 2510 may adjust the height of the substrate chuck 2300 such that the gap between the backplane substrate 3000 and the deposition mask 4000 becomes a predetermined gap, e.g., a gap of several μm. In another embodiment, for example, the hexapod actuator 2510 may adjust the height of the substrate chuck 2300 such that the backplane substrate 3000 is brought into contact with the deposition mask 4000.

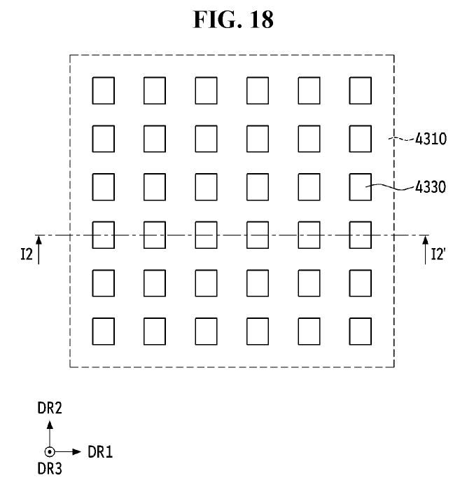

After the backplane substrate 3000 is positioned on the deposition mask 4000, the deposition source 2200 may provide a vapor deposition material onto the backplane substrate 3000 through the deposition mask 4000, thereby forming a deposition material layer on the backplane substrate 3000. In an embodiment, for example, the deposition source 2200 may provide a vapor light emitting material for forming light emitting layers on the backplane substrate 3000, and the vapor light emitting material may be deposited on the electrode patterns of the backplane substrate 3000 through pixel openings 4330 (see FIG. 18) of the deposition mask 4000.

FIG. 16 is a schematic bottom view illustrating the backplane substrate shown in FIG. 15.

Referring to FIG. 16, an embodiment of the backplane substrate 3000 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 16, and may be individualized into the display panels 100 (see FIG. 3) by a dicing process after the display manufacturing process is completed. For example, the first direction DR1 may be a first horizontal direction, and the second direction DR2 may be a second horizontal direction perpendicular to the first direction DR1. In addition, each of the display cell regions 3010 may have, for example, a quadrilateral shape as shown in FIG. 16.

In an embodiment, for example, each of the display cell regions 3010 may include the semiconductor backplane SBP and the light emitting element backplane EBP disposed on the semiconductor backplane SBP, as shown in FIG. 11. In addition, a plurality of electrode patterns, e.g., the plurality of first electrodes AND may be disposed on the light emitting element backplane EBP, and the pixel defining film PDL having openings that expose the first electrodes AND may be disposed on the light emitting element backplane EBP and the first electrodes AND. In this case, the electrode patterns of the display cell regions 3010 may be arranged on the front surface of the backplane substrate 3000, and the substrate chuck 2300 may hold the rear surface of the backplane substrate 3000 such that the electrode patterns of the display cell regions 3010 face downward, i.e., face the deposition source 2200.

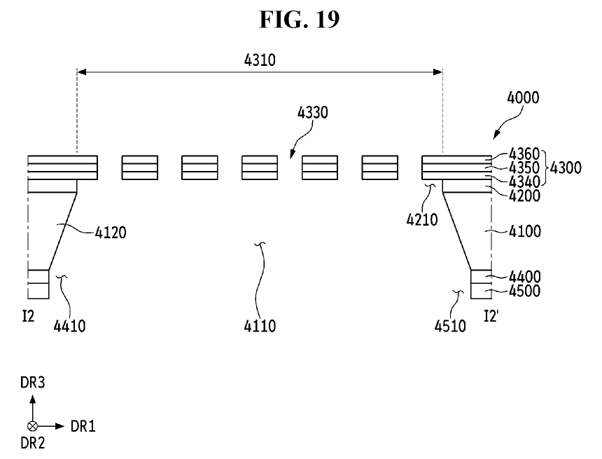

FIG. 17 is a schematic plan view illustrating the deposition mask shown in FIG. 15. FIG. 18 is a schematic plan view illustrating the mask cell regions shown in FIG. 17. FIG. 19 is a schematic cross-sectional view taken along line I2-I2' shown in FIG. 18.

Referring to FIGS. 17-19, an embodiment of the deposition mask 4000 may include mask cell regions 4310 respectively corresponding to the display cell regions 3010 of the backplane substrate 3000, and a grid region 4320 corresponding to the scribe lane region 3020 of the backplane substrate 3000. Each of the mask cell regions 4310 may be provided with a plurality of pixel openings 4330 exposing the electrode patterns of the backplane substrate 3000 in a deposition process. In an embodiment, for example, when the backplane substrate 3000 is positioned on the deposition mask 4000 in the deposition process, the electrode patterns, e.g., the first electrodes AND, of the backplane substrate 3000 may be positioned on the pixel openings 4330 of the deposition mask 4000, and accordingly, the first electrodes AND may be exposed toward the deposition source 2200 through the pixel openings 4330.

According to an embodiment, the deposition mask 4000 may include a mask substrate 4100, a buffer inorganic film 4200 disposed on the mask substrate 4100, and a membrane 4300 disposed on the buffer inorganic film 4200. According to an embodiment, the membrane 4300 may include the plurality of mask cell regions 4310 and the grid region 4320 surrounding the mask cell regions 4310, and each of the mask cell regions 4310 may be provided with the plurality of pixel openings 4330.

According to an embodiment, the mask substrate 4100 may be provided with cell openings 4110 respectively corresponding to the mask cell regions 4310, and may include a rib region 4120 defining the cell openings 4110. The buffer inorganic film 4200 may be provided with first buffer openings 4210 respectively arranged on the cell openings 4110. In this case, the mask cell regions 4310 of the membrane 4300 may be respectively arranged on the first buffer openings 4210, and the pixel openings 4330 of the membrane 4300 may be connected to the cell openings 4110 through the first buffer openings 4210.

According to an embodiment, the mask cell regions 4310 of the membrane 4300 may be regions exposed toward the deposition source 2200 through the cell openings 4110 of the mask substrate 4100 and the first buffer openings 4210 of the buffer inorganic film 4200, and the pixel openings 4330 may be formed to penetrate the mask cell regions 4310. In this case, while performing the deposition process, the vapor deposition material provided from the deposition source 2200 may be deposited on the first electrodes AND of the backplane substrate 3000 through the cell openings 4110, the first buffer openings 4210, and the pixel openings 4330.

According to an embodiment, as shown in FIG. 17, the mask cell regions 4310 may be arranged in a matrix form along the first direction DR1 and the second direction DR2. For example, the first direction DR1 may be the first horizontal direction, and the second direction DR2 may be the second horizontal direction perpendicular to the first direction DR1. The mask cell regions 4310 may have, for example, a quadrilateral shape as shown in FIG. 17, and the pixel openings 4330 may be arranged to correspond to the first electrodes AND of any one of the first emission areas EA1, the second emission areas EA2, and the third emission areas EA3.

According to an embodiment, the mask substrate 4100 may include single crystal silicon. In an embodiment, for example, a single crystal silicon substrate having a thickness in a range of about 700 μm to about 800 μm, e.g., about 725 μm or about 775 μm, may be used as the mask substrate 4100.

According to an embodiment, the buffer inorganic film 4200 and the membrane 4300 may be disposed on a front surface of the mask substrate 4100, and an intermediate inorganic film 4400 and a rear inorganic film 4500 may be disposed on a rear surface of the mask substrate 4100. In an embodiment, for example, the intermediate inorganic film 4400 may be disposed on the rear surface of the mask substrate 4100, and the rear inorganic film 4500 may be disposed on the intermediate inorganic film 4400.

According to an embodiment, the intermediate inorganic film 4400 and the rear inorganic film 4500 may respectively be provided with intermediate openings 4410 and rear openings 4510 that communicate with the cell openings 4110. According to an embodiment, the intermediate inorganic film 4400 and the rear inorganic film 4500 may function as an etching mask in an etching process for forming the cell openings 4110. In this case, the mask cell regions 4310 may be exposed toward the deposition source 2200 through the first buffer openings 4210, the cell openings 4110, the intermediate openings 4410, and the rear openings 4510. In addition, the vapor deposition material provided from the deposition source 2200 during the deposition process may be deposited on the first electrodes AND of the backplane substrate 3000 through the rear openings 4510, the intermediate openings 4410, the cell openings 4110, the first buffer openings 4210, and the pixel openings 4330.

According to an embodiment, the buffer inorganic film 4200, the intermediate inorganic film 4400, and the rear inorganic film 4500 may include a material having etching selectivity with respect to the mask substrate 4100. In an embodiment, for example, the buffer inorganic film 4200 and the intermediate inorganic film 4400 may include silicon oxide (SiOₓ), and the rear inorganic film 4500 may include silicon nitride (SiNₓ). In an embodiment, for example, the buffer inorganic film 4200 and the intermediate inorganic film 4400 may be formed simultaneously on the front and rear surfaces of the mask substrate 4100 by a thermal oxidation process or a chemical vapor deposition (CVD) process, and the rear inorganic film 4500 may be formed on the intermediate inorganic film b4400 y a CVD process.

According to an embodiment, the cell openings 4110 may be formed to expose the buffer inorganic film 4200, i.e., to penetrate the mask substrate 4100, by an anisotropic etching process using the intermediate inorganic film 4400 and the rear inorganic film 4500 as an etching mask. In an embodiment, for example, a single crystal silicon substrate may be used as the mask substrate 4100, and the cell openings 4110 may be formed by a wet etching process using an etchant such as a tetramethylammonium hydroxide (TMAH) solution, or a potassium hydroxide (KOH) solution. In this case, the <100> crystal direction of the single crystal silicon substrate used as the mask substrate 4100 may be the third direction DR3, and accordingly, the cell openings 4110 may have a width that gradually decreases from the rear surface of the mask substrate 4100 toward the front surface of the mask substrate 4100 through the wet etching process. In an embodiment, for example, the inner side surfaces of the cell openings 4110 may have an inclination angle of about 54.7° with respect to the rear surface of the mask substrate 4100.

In another embodiment, for example, the cell openings 4110 may be formed by a deep reactive ion etching (DRIE) process or a cryogenic etching process.

According to an embodiment, the first buffer openings 4210 of the buffer inorganic film 4200 may be formed by a wet etching process after forming the cell openings 4110 of the mask substrate 4100. In an embodiment, for example, where the buffer inorganic film 4200 includes silicon oxide (SiOₓ), the first buffer openings 4210 may be formed by a wet etching process using an etchant such as buffered oxide etchant (BOE) or diluted HF.

According to an embodiment, the membrane 4300 may be disposed on the buffer inorganic film 4200 and may include a first electrode film 4340, a piezoelectric material film 4350, and a second electrode film 4360. In an embodiment, for example, the membrane 4300 may include the first electrode film 4340 disposed on the buffer inorganic film 4200, the piezoelectric material film 4350 disposed on the first electrode film 4340, and the second electrode film 4360 disposed on the piezoelectric material film 4350. According to an embodiment, the first electrode film 4340 and the second electrode film 4360 may include a conductive material. In an embodiment, for example, the first electrode film 4340 and the second electrode film 4360 may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In another embodiment, for example, the first electrode film 4340 and the second electrode film 4360 may include transparent conductive oxide such as indium tin oxide (ITO), indium zinc oxide (IZO), or the like. According to an embodiment, the piezoelectric material film 4350 may include a piezoelectric material such as aluminum nitride (AlN), zinc oxide (ZnO), lead zirconate titanate (PZT), barium titanate (BaTiO₃), or the like.

According to an embodiment, when a voltage or a potential difference is provided between the first electrode film 4340 and the second electrode film 4360, the piezoelectric material film 4350 may be deformed by a converse piezoelectric effect. In an embodiment, for example, when a contraction force is generated in the piezoelectric material film 4350 in the third direction DR3 by a voltage or a potential difference between the first electrode film 4340 and the second electrode film 4360, the piezoelectric material film 4350 may expand in the first direction DR1 and the second direction DR2 by the contraction force, thereby reducing the sagging or warpage of the membrane 4300.

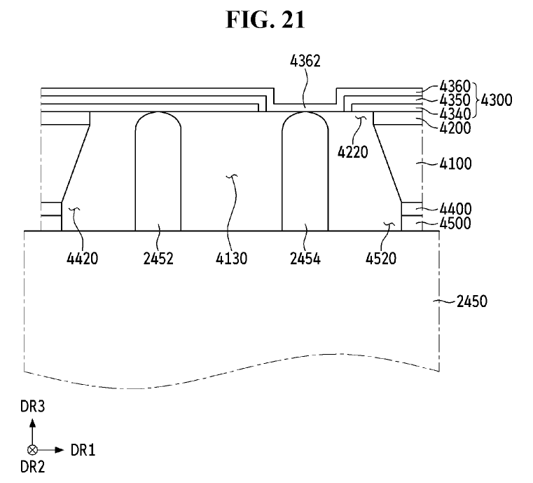

In an embodiment, for example, when the deposition mask 4000 is placed on the mask chuck 2400, the deposition mask 4000 and/or the mask cell regions 4310 of the membrane 4300 may sag due to their own weights. According to an embodiment, when the deposition mask 4000 is placed on the mask chuck 2400, a driving voltage may be applied to the first electrode film 4340 and the second electrode film 4360 by a power supply unit 2450 (see FIG. 21), and thus, a force, that is, a tensile force, expanding the membrane 4300 in the horizontal direction may be applied to the membrane 4300. As a result, the sagging of the deposition mask 4000 and/or warpage or the sagging of the mask cell regions 4310 may be reduced by the tensile force.

According to an embodiment, the deposition apparatus 2000 may include the power supply unit 2450 for applying a driving voltage to the membrane 4300. In an embodiment, for example, the power supply unit 2450 may be mounted on the mask chuck 2400. When the deposition mask 4000 is placed on the mask chuck 2400, the power supply unit 2450 may be electrically connected to the first electrode film 4340 and the second electrode film 4360 of the membrane 4300.

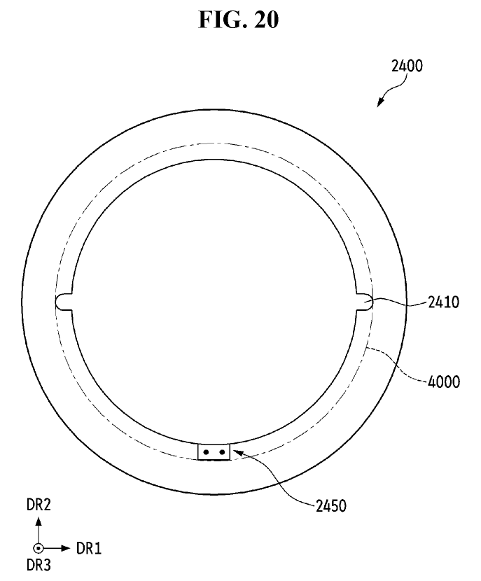

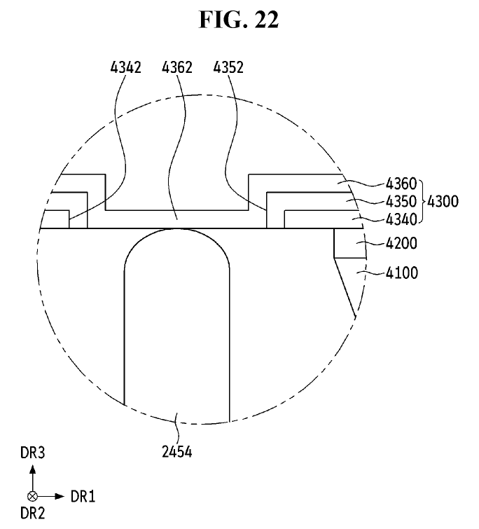

FIG. 20 is a schematic plan view illustrating a mask chuck and a power supply unit according to an embodiment. FIG. 21 is a schematic enlarged cross-sectional view illustrating electrical connection between a power supply unit and a membrane. FIG. 22 is a schematic enlarged cross-sectional view illustrating a contact pad shown in FIG. 21.

Referring to FIGS. 20-22, in an embodiment, the mask chuck 2400 may support the edge portion of the deposition mask 4000. According to an embodiment, the mask chuck 2400 may have a substantially circular ring shape, and the power supply unit 2450 may be mounted within the mask chuck 2400. In an embodiment, for example, the deposition mask 4000 may be placed on the mask chuck 2400 and the power supply unit 2450, and the power supply unit 2450 may include a first contact plug 2452 and a second contact plug 2454 for electrical connection with the first electrode film 4340 and the second electrode film 4360.

According to an embodiment, as shown in FIG. 22, the first electrode film 4340 may define a first contact hole 4342, and the piezoelectric material film 4350 may define a second contact hole 4352 disposed in the first contact hole 4342. In an embodiment, for example, the first contact hole 4342 may penetrate (or be defined through) the first electrode film 4340, and the second contact hole 4352 may penetrate (or be defined through) the piezoelectric material film 4350. According to an embodiment, the second electrode film 4360 may include a contact pad 4362 disposed in the second contact hole 4352. In an embodiment, for example, the second electrode film 4360 may be formed on the piezoelectric material film 4350 and in the second contact hole 4352, and a portion of the second electrode film 4360 formed in the second contact hole 4352 may be used as the contact pad 4362. In an embodiment, for example, the first contact hole 4342, the second contact hole 4352, and the contact pad 4362 may be disposed on the edge portion of the mask substrate 4100.

According to an embodiment, the second contact hole 4352 may have a size (or a planar area) less than that of the first contact hole 4342, and the piezoelectric material film 4350 may be formed on the inner side surface of the first contact hole 4342. Accordingly, the contact pad 4362 may be electrically insulated from the first electrode film 4340 by the piezoelectric material film 4350.

According to an embodiment, as shown in FIG. 21, the mask substrate 4100 may be provided with a contact opening 4130, and the buffer inorganic film 4200 may be provided with a second buffer opening 4220 disposed on the contact opening 4130. In addition, the intermediate inorganic film 4400 may be provided with a second intermediate opening 4420, and the rear inorganic film 4500 may be provided with a second rear opening 4520. According to an embodiment, the contact opening 4130 may be formed by a wet etching process using the intermediate inorganic film 4400 and the rear inorganic film 4500 as an etching mask. In an embodiment, for example, the contact opening 4130 may be formed simultaneously with the cell openings 4110 by a wet etching process using an etchant such as a tetramethylammonium hydroxide (TMAH) solution, a potassium hydroxide (KOH) solution, or the like. According to an embodiment, the second buffer opening 4220 may be formed by a wet etching process after forming the contact opening 4130. In an embodiment, for example, the second buffer opening 4220 may be formed simultaneously with the first buffer openings 4210 by a wet etching process using an etchant such as a buffered oxide etchant (BOE), diluted hydrofluoric acid, or the like.

According to an embodiment, a portion of the first electrode film 4340 and the contact pad 4362 may be exposed by the second buffer opening 4220, the contact opening 4130, the second intermediate opening 4420, and the second rear opening 4520. The first contact plug 2452 and the second contact plug 2454 may protrude upward from the top surface of the mask chuck 2400. In an embodiment, for example, when the deposition mask 4000 is placed on the mask chuck 2400 and the power supply unit 2450, the first contact plug 2452 and the second contact plug 2454 may be in contact with the portion of the first electrode film 4340 and the contact pad 4362, respectively, through the second rear opening 4520, the second intermediate opening 4420, the contact opening 4130, and the second buffer opening 4220, and a driving voltage may be applied to the first electrode film 4340 and the second electrode film 4360 through the first contact plug 2452 and the second contact plug 2454. In addition, a tensile force may be applied to the membrane 4300 in the first direction DR1 and the second direction DR2 due to the converse piezoelectric effect of the piezoelectric material film 4350. Thus, the sagging of the deposition mask 4000 and the sagging and/or warpage of the mask cell regions 4310 may be reduced.

Referring back to FIG. 17, the deposition mask 4000 may include the mask alignment key 4600. In an embodiment, for example, the mask alignment keys 4600 may be arranged on the edge portions of the mask substrate 4100, and the substrate alignment keys 3100 of the backplane substrate 3000 and the mask alignment keys 4600 of the deposition mask 4000 may be detected by the cameras 2700 (see FIG. 15). Although not shown in detail, the cameras 2700 may be connected to a lower portion of the mask chuck 2400, and the mask chuck 2400 may include through slots 2410 or through holes formed in the third direction DR3 to detect the substrate alignment keys 3100 and the mask alignment keys 4600, as shown in FIG. 20. In addition, although not shown, the substrate chuck 2300 may be equipped with lighting devices (not shown) providing light, for example, infrared illumination light, which may pass through the backplane substrate 3000 and the deposition mask 4000. The cameras 2700 may detect illumination light transmitted through the backplane substrate 3000 and the deposition mask 4000.

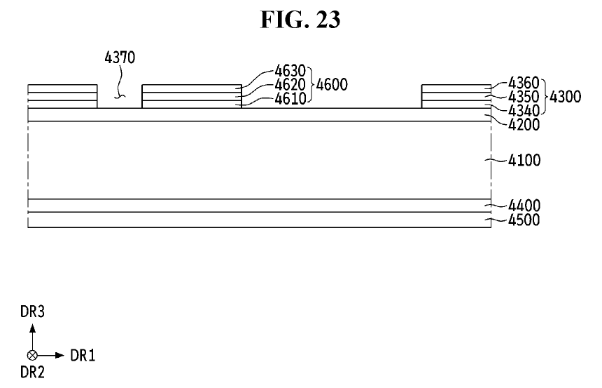

FIG. 23 is a schematic cross-sectional view illustrating the mask alignment key shown in FIG. 17.

Referring to FIG. 23, the mask alignment key 4600 may be disposed on the mask substrate 4100, and the membrane 4300 may be provided with a key opening 4370. According to an embodiment, the key opening 4370 may expose a portion of the buffer inorganic film 4200, and the mask alignment key 4600 may be disposed on the exposed portion of the buffer inorganic film 4200. In an embodiment, for example, the mask alignment key 4600 may be disposed in the key opening 4370 and may be spaced apart from the inner side surface of the key opening 4370. That is, the key opening 4370 may have a ring shape surrounding the mask alignment key 4600.

According to an embodiment, the mask alignment key 4600 may include a first alignment key 4610 disposed on the buffer inorganic film 4200, a second alignment key 4620 disposed on the first alignment key 4610, and a third alignment key 4630 disposed on the second alignment key 4620. In an embodiment, for example, the first alignment key 4610 may include the same material as the first electrode film 4340, the second alignment key 4620 may include the same material as the piezoelectric material film 4350, and the third alignment key 4630 may include the same material as the second electrode film 4360. In an embodiment, for example, after forming the membrane 4300 on the buffer inorganic film 4200, the key openings 4370 and the mask alignment keys 4600 may be formed by patterning the membrane 4300.

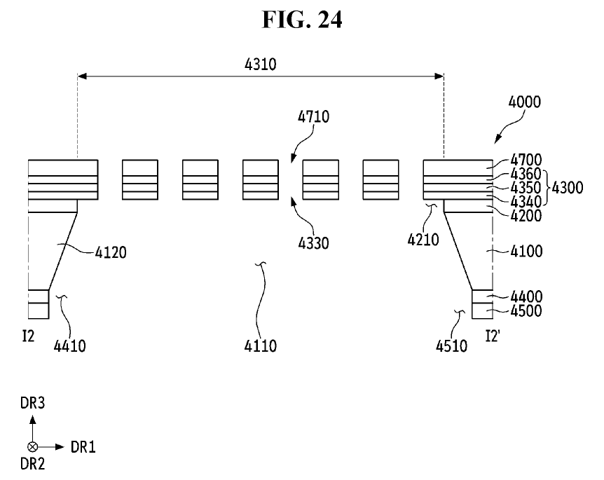

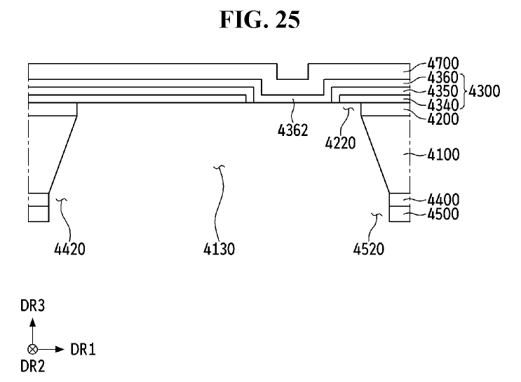

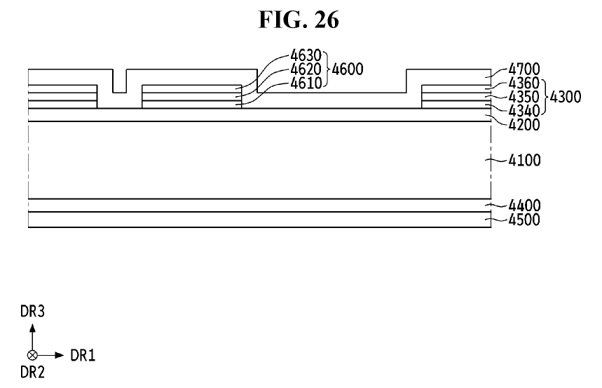

FIG. 24 is a schematic cross-sectional view illustrating another example of the deposition mask shown in FIG. 15. FIGS. 25 and 26 are schematic cross-sectional views illustrating a reinforcement film shown in FIG. 24.

The embodiment of FIGS. 24 to 26 is substantially the same as the embodiment previously described with reference to FIGS. 17 to 23 except that a reinforcement film 4700 is formed on the membrane 4300. In description of the embodiment of FIGS. 24 to 26, any repetitive detailed description of the same or like elements as those described above with reference to FIGS. 17 to 23 will be omitted.

Referring to FIGS. 24 to 26, in an embodiment, the reinforcement film 4700 may be disposed on the membrane 4300. According to an embodiment, the reinforcement film 4700 may include silicon nitride (SiNₓ) and may be formed on the membrane 4300 by a CVD process. For example, the reinforcement film 4700 may be formed simultaneously with the rear inorganic film 4500 by a low pressure chemical vapor deposition (LPCVD) process. According to an embodiment, the reinforcement film 4700 may be used to improve the rigidity of the membrane 4300, thereby reducing the sagging and/or warpage of the membrane 4300. According to an embodiment, the reinforcement film 4700 may define second pixel openings 4710 respectively connected to the pixel openings 4330. In an embodiment, for example, the second pixel openings 4710 and the pixel openings 4330 may be sequentially formed by an anisotropic etching process, e.g., a plasma etching process or an RIE process.

According to an embodiment, as shown in FIG. 25, the reinforcement film 4700 may be disposed on the membrane 4300 and the contact pad 4362. In an embodiment, for example, the reinforcement film 4700 may be formed conformally on the second electrode film 4360 and the contact pad 4362 to have a substantially uniform thickness. Thus, the rigidity of the contact pad 4362 may be greatly improved. In addition, as shown in FIG. 26, the reinforcement film 4700 may be disposed on the membrane 4300 and the mask alignment key 4600. In an embodiment, for example, the reinforcement film 4700 may be formed conformally on the membrane 4300, the key opening 4370 (see FIG. 23), and the mask alignment key 4600 to have a substantially uniform thickness. In this case, the reinforcement film 4700 may function as a passivation film to protect the mask alignment key 4600.

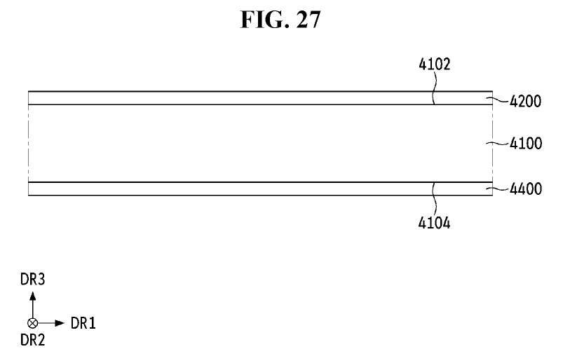

FIGS. 27 to 38 are schematic cross-sectional views illustrating a method of manufacturing a deposition mask according to an embodiment of the present disclosure.

Referring to FIG. 27, in an embodiment of a method of manufacturing a deposition mask, the buffer inorganic film 4200 may be formed on the mask substrate 4100. According to an embodiment, the mask substrate 4100 may include single crystal silicon. In an embodiment, for example, a single crystal silicon substrate having a thickness in a range of about 700 μm to about 800 μm, e.g., about 725 μm or about 775 μm, may be used as the mask substrate 4100. According to an embodiment, the buffer inorganic film 4200 may include silicon oxide (SiOₓ), and may be formed with a thickness of about 0.2 μm to about 2 μm on a front surface 4102 of the mask substrate 4100 through a thermal oxidation process or a CVD process.

According to an embodiment, the intermediate inorganic film 4400 may be formed on the rear surface 4104 of the mask substrate 4100. According to an embodiment, the intermediate inorganic film 4400 may include silicon oxide (SiOₓ) and may be formed by a thermal oxidation process or a CVD process. In an embodiment, for example, the buffer inorganic film 4200 and the intermediate inorganic film 4400 may be formed simultaneously by a thermal oxidation process or a CVD process. In this case, the intermediate inorganic film 4400 may have a same thickness as the buffer inorganic film 4200.

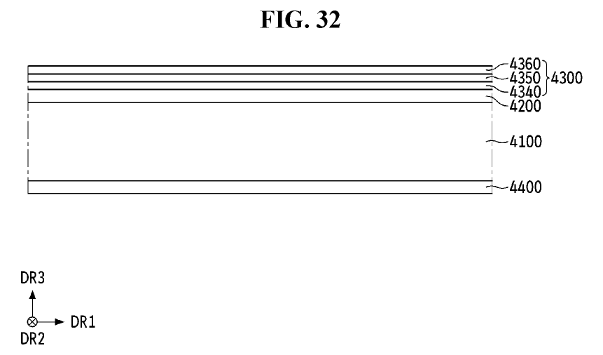

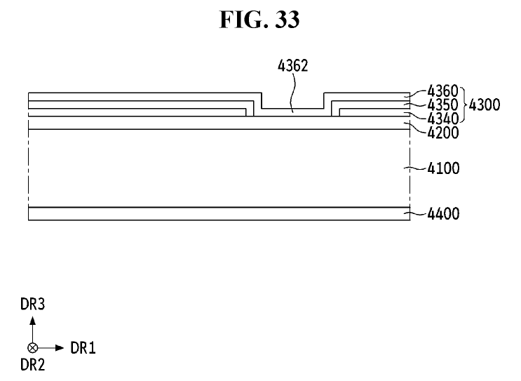

According to an embodiment, the membrane 4300 (see FIGS. 32 and 33) may be formed on the buffer inorganic film 4200. The membrane 4300 may include the first electrode film 4340 formed on the buffer inorganic film 4200, the piezoelectric material film 4350 formed on the first electrode film 4340, and the second electrode film 4360 formed on the piezoelectric material film 4350.

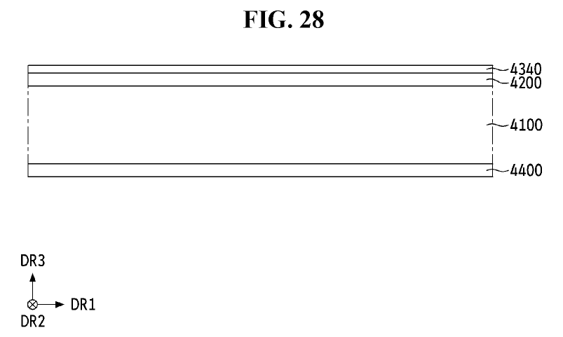

Referring to FIG. 28, in an embodiment of a method of manufacturing a deposition mask, the first electrode film 4340 may be formed on the buffer inorganic film 4200. According to an embodiment, the first electrode film 4340 may include any one of copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In another embodiment, for example, the first electrode film 4340 may include transparent conductive oxide such as indium tin oxide (ITO), indium zinc oxide (IZO), or the like. According to an embodiment, the first electrode film 4340 may be formed to have a thickness of about 0.1 μm to about 1 μm on the buffer inorganic film 4200 by a sputtering process, a CVD process, or the like.

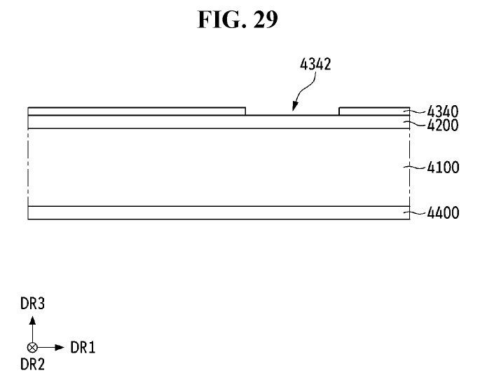

Referring to FIG. 29, in an embodiment of a method of manufacturing a deposition mask, after forming the first electrode film 4340, the first electrode film 4340 may be patterned to form the first contact hole 4342 exposing the buffer inorganic film 4200. In an embodiment, for example, the first contact hole 4342 may be formed by forming, on the first electrode film 4340, a photoresist pattern (not shown) that exposes a portion where the first contact hole 4342 is to be formed, and then performing an anisotropic etching process, e.g., a plasma etching process, using the photoresist pattern as an etching mask. The photoresist pattern described above may be removed by an ashing and/or stripping process after the first contact hole 4342 is formed.

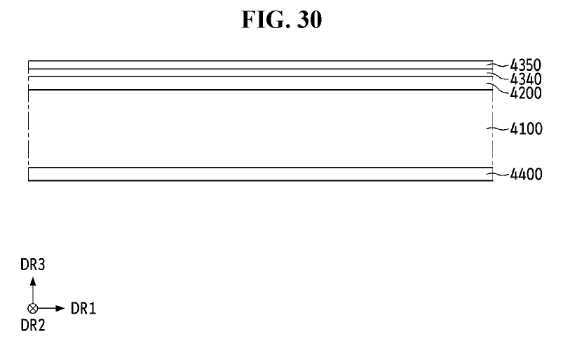

Referring to FIG. 30, in an embodiment of a method of manufacturing a deposition mask, the piezoelectric material film 4350 may be formed on the first electrode film 4340 and a portion of the buffer inorganic film 4200 exposed by the first contact hole 4342. According to an embodiment, the piezoelectric material film 4350 may include a piezoelectric material such as aluminum nitride (AlN), zinc oxide (ZnO), lead zirconate titanate (PZT), barium titanate (BaTiO₃), or the like, and may be formed on the first electrode film 4340 to have a thickness of about 0.1 μm to about 1 μm by a sputtering process, a CVD process, a jet printing process, a hydrothermal synthesis process, or the like.

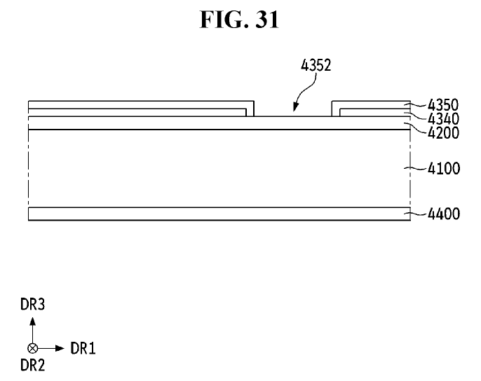

Referring to FIG. 31, in an embodiment of a method of manufacturing a deposition mask, after forming the piezoelectric material film 4350, the piezoelectric material film 4350 may be patterned to form the second contact hole 4352 exposing the buffer inorganic film 4200. In an embodiment, for example, the second contact hole 4352 may be formed by forming, on the piezoelectric material film 4350, a photoresist pattern exposing the portion where the second contact hole 4352 is to be formed, and then performing an anisotropic etching process, e.g., a plasma etching process, using the photoresist pattern as an etching mask. According to an embodiment, the second contact hole 4352 may have a size less than that of the first contact hole 4342 and may partially expose a portion of the buffer inorganic film 4200 exposed by the first contact hole 4342. For example, as shown in FIG. 31, the second contact hole 4352 may be formed such that the inner side surface of the first contact hole 4342 is not exposed. The photoresist pattern described above may be removed by an ashing and/or stripping process after the second contact hole 4352 is formed.

Referring to FIG. 32, in an embodiment of a method of manufacturing a deposition mask, the second electrode film 4360 may be formed on the piezoelectric material film 4350 and a portion of the buffer inorganic film 4200 exposed by the second contact hole 4352. According to an embodiment, the second electrode film 4360 may include any one of copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. As another example, the second electrode film 4360 may include transparent conductive oxide such as indium tin oxide (ITO), indium zinc oxide (IZO), or the like. According to an embodiment, the second electrode film 4360 may be formed to have a thickness of about 0.1 μm to about 1 μm on the piezoelectric material film 4350 by a sputtering process, a CVD process, or the like.

Referring to FIG. 33, in an embodiment of a method of manufacturing a deposition mask, the second electrode film 4360 may be formed on a portion of the buffer inorganic film 4200 exposed by the second contact hole 4352. In this case, a portion of the second electrode film 4360 formed in the second contact hole 4352 may be used as the contact pad 4362.

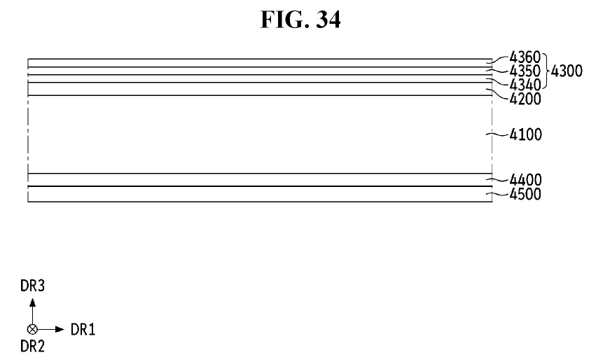

Referring to FIG. 34, in an embodiment of a method of manufacturing a deposition mask, the rear inorganic film 4500 may be formed on the intermediate inorganic film 4400. According to an embodiment, the rear inorganic film 4500 may include silicon nitride (SiNₓ). In an embodiment, for example, the rear inorganic film 4500 may include stoichiometric silicon nitride (Si₃N₄) or silicon-rich silicon nitride, and may be formed on the intermediate inorganic film 4400 by an LPCVD process. In an embodiment, for example, a silicon source gas, such as monosilane (SiH₄), or dichlorosilane (DCS) (SiH₂Cl₂), and a nitrogen source gas, such as N₂ or NH₃, may be supplied onto the intermediate inorganic film 4400, and the rear inorganic film 4500 may be formed with a thickness of about 0.3 μm to about 3 μm by a reaction between the silicon source gas and the nitrogen source gas.

In another embodiment, for example, the rear inorganic film 4500 may be formed before forming the membrane 4300. That is, after the rear inorganic film 4500 is formed on the intermediate inorganic film 4400, the membrane 4300 may be formed on the buffer inorganic film 4200.

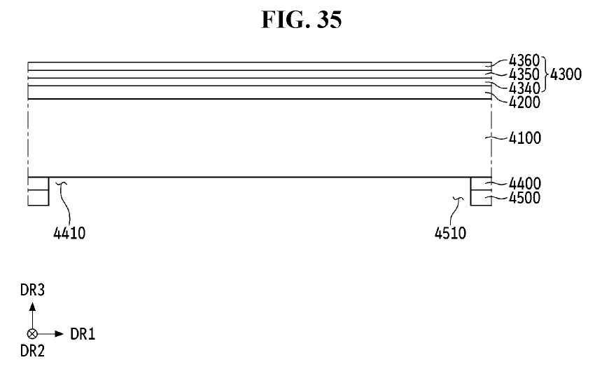

Referring to FIG. 35, in an embodiment of a method of manufacturing a deposition mask, the rear inorganic film 4500 and the intermediate inorganic film 4400 may be partially removed to form the rear openings 4510 and the intermediate openings 4410 that expose rear portions of the mask substrate 4100. In an embodiment, for example, a photoresist pattern (not shown) that exposes portions where the rear openings 4510 are to be formed may be formed on the rear inorganic film 4500, and the rear openings 4510 and the intermediate openings 4410 may be formed by performing an anisotropic etching process, e.g., an RIE process, using the photoresist pattern as an etching mask. The RIE process may be performed until the rear portions of the mask substrate 4100 are exposed, and the photoresist pattern may be removed by an ashing and/or stripping process after the rear openings 4510 and the intermediate openings 4410 are formed.

According to an embodiment, the second intermediate opening 4420 (see FIG. 25) and the second rear opening 4520 (see FIG. 25) that expose the rear edge portion of the mask substrate 4100 may be formed. In an embodiment, for example, a photoresist pattern (not shown) exposing the portion where the second rear opening 4520 is to be formed, may be formed on the rear inorganic film 4500, and the second rear opening 4520 and the second intermediate opening 4420 may be formed by performing an anisotropic etching process, e.g., an RIE process, using the photoresist pattern as an etching mask. The RIE process may be performed until the rear edge portion of the mask substrate 4100 is exposed, and the photoresist pattern may be removed by an ashing process and/or a strip process after the second rear opening 4520 and the second intermediate opening 4420 are formed. According to an embodiment, the rear openings 4510, the second rear opening 4520, the intermediate openings 4410, and the second intermediate opening 4420 may be formed simultaneously.

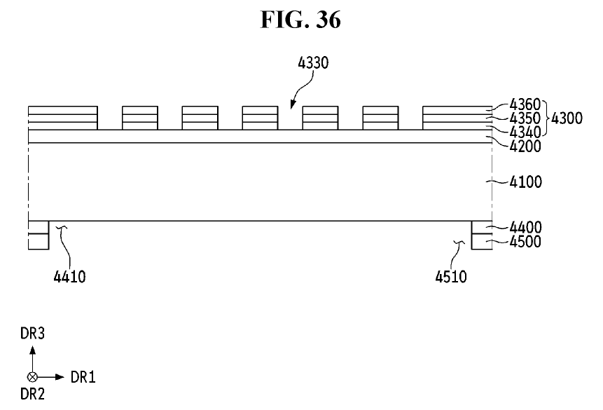

Referring to FIG. 36, in an embodiment of a method of manufacturing a deposition mask, the pixel openings 4330 may be formed by patterning the membrane 4300. According to an embodiment, the pixel openings 4330 penetrating the membrane 4300 may be formed by forming, on the membrane 4300, a photoresist pattern (not shown) exposing the portions where the pixel openings 4330 are to be formed, and then performing an anisotropic etching process, e.g., a plasma etching process, using the photoresist pattern as an etching mask. In an embodiment, for example, the anisotropic etching process may be performed until the buffer inorganic film 4200 is exposed, and the photoresist pattern may be removed by an ashing process and/or a strip process after the pixel openings 4330 are formed.

According to an embodiment, the membrane 4300 may be patterned to form the mask alignment keys 4600 (see FIG. 23) and the key openings 4370 (see FIG. 23). In an embodiment, for example, the key openings 4370 and the mask alignment keys 4600 may be formed by forming, on the membrane 4300, a photoresist pattern (not shown) exposing the portions where the key openings 4370 are to be formed other than the portions where the mask alignment keys 4600 are to be formed, and then performing an anisotropic etching process, e.g., a plasma etching process, using the photoresist pattern as an etching mask. According to an embodiment, the mask alignment keys 4600 may be disposed in the key openings 4370, respectively, and the anisotropic etching process may be performed until the buffer inorganic film 4200 is exposed. In addition, each of the mask alignment keys 4600 may include the first alignment key 4610 containing the same material as the first electrode film 4340, the second alignment key 4620 containing the same material as the piezoelectric material film 4350, and the third alignment key 4630 containing the same material as the second electrode film 4360. According to an embodiment, the pixel openings 4330, the key openings 4370, and the mask alignment keys 4600 may be formed simultaneously.

In another embodiment, for example, the pixel openings 4330, the key openings 4370, and the mask alignment keys 4600 may be formed before forming the rear openings 4510, the second rear opening 4520, the intermediate openings 4410, and the second intermediate opening 4420. That is, after the pixel openings 4330, the key openings 4370, and the mask alignment keys 4600 are formed, the rear openings 4510, the second rear opening 4520, the intermediate openings 4410, and the second intermediate opening 4420 may be formed.

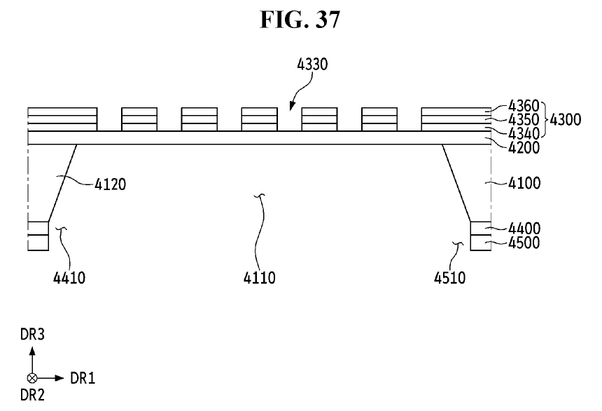

Referring to FIG. 37, in an embodiment of a method of manufacturing a deposition mask, the mask substrate 4100 may be partially removed to form the cell openings 4110 that expose the buffer inorganic film 4200. According to an embodiment, the cell openings 4110 may be formed through an anisotropic etching process using the rear inorganic film 4500 and the intermediate inorganic film 4400 as an etching mask. In an embodiment, for example, the cell openings 4110 may be formed by a wet etching process that uses an etchant such as a TMAH solution or a KOH solution, and the wet etching process may be performed until the buffer inorganic film 4200 is exposed. In addition, according to an embodiment, the contact opening 4130 (see FIG. 21) penetrating the edge portion of the mask substrate 4100 may be formed by a wet etching process.

According to an embodiment, the <100> crystal direction of the single crystal silicon substrate used as the mask substrate 4100 may be the third direction DR3, and accordingly, the cell openings 4110 and the contact openings 4130 may have a width that gradually decreases from the rear surface 4104 of the mask substrate 4100 toward the front surface 4102 of the mask substrate 4100 through the wet etching process. In an embodiment, for example, inner side surfaces of the cell openings 4110 and the contact openings 4130 may have an inclination angle of about 54.7° with respect to the rear surface 4104 of the mask substrate 4100.

According to an embodiment, the buffer inorganic film 4200 may function as an etch stop film during the formation of the cell openings 4110. In an embodiment, for example, where the buffer inorganic film 4200 is omitted, the etchant may be provided onto the front surface 4102 of the mask substrate 4100 through the pixel openings 4330, and hydrogen bubbles may be generated in the pixel openings 4330 by a reaction between the etchant and the mask substrate 4100. In such an embodiment, the membrane 4300 may be damaged by the hydrogen bubbles. The buffer inorganic film 4200 may effectively prevent an etchant from being provided onto the front surface 4102 of the mask substrate 4100 through the pixel openings 4330, thereby effectively preventing damage to the membrane 4300.

In another embodiment, for example, the cell openings 4110 and the contact opening 4130 may be formed by a DRIE process or a cryogenic etching process. In such an embodiment, the rear inorganic film 4500 may be used as an etching mask, and the DRIE process or the cryogenic etching process may be performed until the buffer inorganic film 4200 is exposed.

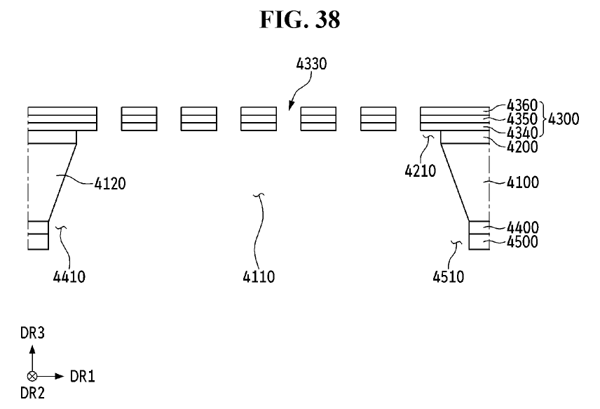

Referring to FIG. 38, portions of the buffer inorganic film 4200 exposed by the cell openings 4110 may be removed to form the first buffer openings 4210 that connect the pixel openings 4330 to the cell openings 4110. In addition, a portion of the buffer inorganic film 4200 exposed by the contact opening 4130 may be removed to form the second buffer opening 4220 (see FIG. 21) that exposes a portion of the first electrode film 4340 and the contact pad 4362. According to an embodiment, when the buffer inorganic film 4200 includes silicon oxide (SiOₓ), the first buffer openings 4210 and the second buffer opening 4220 may be formed simultaneously by a wet etching process using an etchant such as BOE, diluted HF or the like.

According to another embodiment, after forming the mask alignment keys 4600, the reinforcement film 4700 (see FIGS. 24 to 26) may be formed on the membrane 4300, the key openings 4370, the mask alignment keys 4600, and the contact pad 4362. In an embodiment, for example, the reinforcement film 4700 may include silicon nitride (SiNₓ) and may be formed simultaneously with the rear inorganic film 4500 by an LPCVD process. Subsequently, the reinforcement film 4700 and the membrane 4300 may be patterned to form the second pixel openings 4710 (see FIG. 24) and the pixel openings 4330. In an embodiment, for example, the second pixel openings 4710 and the pixel openings 4330 exposing the buffer inorganic film 4200 may be formed by forming, on the reinforcement film 4700, a photoresist pattern (not shown) that exposes the portions where the second pixel openings 4710 are to be formed, and performing an anisotropic etching process, e.g., a plasma etching process or an RIE process, using the photoresist pattern as an etching mask.

According to embodiments of the present disclosure, as described above, the membrane 4300 may include the first electrode film 4340, the piezoelectric material film 4350, and the second electrode film 4360. In the deposition process for forming the light emitting layers, a driving voltage may be applied to the first electrode film 4340 and the second electrode film 4360, such that a tensile force may be applied to the membrane 4300 in the horizontal direction, for example, in the first direction DR1 and the second direction DR2, due to the converse piezoelectric effect. Accordingly, the sagging of the deposition mask 4000 and the mask cell regions 4310 due to their own weights may be substantially reduced. As a result, the pixel position accuracy (PPA) and the size uniformity of the light emitting layers formed on the backplane substrate 3000 may be substantially improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate provided with a cell opening; and
a membrane disposed on the mask substrate and provided with pixel openings connected to the cell opening,
wherein the membrane comprises a first electrode film disposed on the mask substrate, a piezoelectric material film disposed on the first electrode film, and a second electrode film disposed on the piezoelectric material film.

2. The deposition mask of claim 1, wherein the first electrode film defines a first contact hole,
the piezoelectric material film defines a second contact hole disposed in the first contact hole in a plan view, and
the second electrode film comprises a contact pad disposed in the second contact hole.

3. The deposition mask of claim 2, wherein the mask substrate is provided with a contact opening exposing a portion of the first electrode film and the contact pad.

4. The deposition mask of claim 3, further comprising a buffer inorganic film disposed between the mask substrate and the membrane,
wherein the buffer inorganic film defines a first buffer opening connected to the cell opening and a second buffer opening connected to the contact opening.

5. The deposition mask of claim 2, further comprising a reinforcement film disposed on the second electrode film and the contact pad.

6. The deposition mask of claim 1, further comprising a reinforcement film disposed on the membrane,
wherein the reinforcement film defines second pixel openings respectively connected to the pixel openings.

7. The deposition mask of claim 1, further comprising a mask alignment key arranged on the mask substrate.

8. The deposition mask of claim 7, wherein the membrane is provided with a key opening, and
the mask alignment key is disposed in the key opening.

9. The deposition mask of claim 8, further comprising a reinforcement film disposed on the membrane, the key opening, and the mask alignment key.

10. The deposition mask of claim 7, wherein the mask alignment key comprises:
a first alignment key comprising a same material as the first electrode film;
a second alignment key disposed on the first alignment key and comprising a same material as the piezoelectric material film; and
a third alignment key disposed on the second alignment key and comprising a same material as the second electrode film.

11. A method of manufacturing a deposition mask, the method comprising:
forming a membrane on a mask substrate;
forming pixel openings through the mask substrate; and
forming a cell opening connected to the pixel openings through the mask substrate,
wherein the membrane comprises a first electrode film disposed on the mask substrate, a piezoelectric material film disposed on the first electrode film, and a second electrode film disposed on the piezoelectric material film.

12. The method of claim 11, wherein the forming the membrane comprises:
forming the first electrode film on the mask substrate;
forming a first contact hole through the first electrode film;
forming the piezoelectric material film on the first electrode film and the first contact hole;
forming a second contact hole through the piezoelectric material film in the first contact hole; and
forming the second electrode film on the piezoelectric material film and the second contact hole.

13. The method of claim 12, further comprising forming a contact opening through the mask substrate,
wherein the contact opening is formed to expose a portion of the first electrode film and a portion of the second electrode film formed in the second contact hole.

14. The method of claim 13, further comprising:
forming a buffer inorganic film on the mask substrate; and
forming a first buffer opening and a second buffer opening through the buffer inorganic film on the cell opening and the contact opening.

15. The method of claim 12, further comprising forming a reinforcement film on the second electrode film.

16. The method of claim 11, further comprising:
forming a reinforcement film on the membrane; and
forming second pixel openings through the reinforcement film,
wherein the second pixel openings are respectively connected to the pixel openings.

17. The method of claim 11, further comprising patterning the membrane to form a mask alignment key and a key opening surrounding the mask alignment key on the mask substrate.

18. The method of claim 17, further comprising forming a reinforcement film on the membrane, the key opening, and the mask alignment key.

19. An electronic device comprising a display panel,
wherein the display panel comprises a backplane substrate and a plurality of light emitting layers formed on the backplane substrate by using a deposition mask,
the deposition mask comprises a mask substrate provided with a cell opening, and a membrane disposed on the mask substrate and provided with pixel openings connected to the cell opening,
the membrane comprises a first electrode film disposed on the mask substrate, a piezoelectric material film disposed on the first electrode film, and a second electrode film disposed on the piezoelectric material film, and
the plurality of light emitting layers is formed by a deposition process which provides a vapor deposition material through the cell opening and the pixel openings.

20. The electronic device of claim 19, further comprising at least one selected from a processor, a memory, and a power module.
